(19) United States
(12) Patent Application Publication
(10) Pub. No.: US 2010/0247867 A1
(43) Pub. Date: Sep. 30, 2010

(54) RELIEF PRINTING PLATE PRECURSOR FOR LASER ENGRAVING, RESIN COMPOSITION FOR LASER ENGRAVING, RELIEF PRINTING PLATE, AND METHOD FOR MANUFACTURING RELIEF PRINTING PLATE

(75) Inventor: Kenta YOSHIDA, Shizuoka-ken (JP)

Correspondence Address: Solaris Intellectual Property Group, PLLC, 401 Holland Lane, Suite 407, Alexandria, VA, 22314, US

(73) Assignee: FUJIFILM CORPORATION, Tokyo (JP)

(21) Appl. No.: 12/731,165

(22) Filed: Mar. 25, 2010

(30) Foreign Application Priority Data
Mar. 27, 2009 (JP) 2009-080113
Mar. 8, 2010 (JP) 2010-050696

(51) Int. Cl. B32B 3/30; G03F 7/004; G03F 7/20

(52) U.S. Cl. 428/156; 430/270.1; 430/286.1; 430/306

(57) ABSTRACT

A resin composition for laser engraving is provided, which forms a film having good physical properties, imparts good printing durability to a printing plate having a relief forming layer made of the resin composition, and achieves high engraving sensitivity in laser engraving. The resin composition for laser engraving includes a compound (A) having at least two isocyanate groups in its molecule, and a polymer compound (B) having at least one substituent selected from the group consisting of a hydroxyl group and —NHR, in which R represents a hydrogen atom, a linear alkyl group, a branched alkyl group, an alkenyl group, an alkynyl group, a cycloalkyl group, an alkoxy group, an aryl group, or a heterocyclic group.

### CROSS REFERENCE TO RELATED APPLICATION

This application claims priority under 35 USC 119 from Japanese Patent Application Nos. 2009-080113 filed on Mar. 27, 2009 and 2010-050696 filed on Mar. 8, 2010, the disclosures of which are incorporated by reference herein.

### BACKGROUND OF THE INVENTION

1. Field of the Invention

The present invention relates to a relief printing plate precursor for laser engraving, a resin composition for laser engraving, a relief printing plate, and a method for manufacturing a relief printing plate.

2. Description of the Related Art

As a method of forming recesses and projections on a photosensitive resin layer laminated on a support surface to form a printing plate, a method of exposing a relief forming layer formed using a photosensitive composition with ultraviolet light via an original image film to selectively cure an image area, and removing an uncured area with a developer, so-called “analog platemaking”, is well known.

A relief printing plate is a letterpress printing plate including a relief layer having recesses and projections, and such a relief layer having recesses and projections is obtained by patterning a relief forming layer containing, as a main component, a photosensitive composition containing an elastomeric polymer such as a synthetic rubber, a resin such as a thermoplastic resin, or a mixture of a resin and a plasticizer, to form recesses and projections. Among such relief printing plates, a printing plate having a soft relief layer is sometimes called a flexographic printing plate.

When a relief printing plate is made by analog platemaking, generally, since an original image film using a silver salt material is required, production time and costs for the original image film are necessary. Further, since chemical treatment is necessary for developing an original image film, and disposal of a development waste solution is also necessary, even simpler processes for producing a plate such as, for example, a method not using an original image film, and a method not requiring development treatment are being studied.

In recent years, a method of platemaking of a relief forming layer by scanning light exposure without using an original film is being studied.

For a procedure not requiring an original film, a relief printing plate precursor has been proposed in which a laser-sensitive mask layer element which can form an image mask is provided on a relief forming layer (see, e.g., Japanese Patent No. 2773847 and Japanese Patent Application Laid-Open (JP-A) No. 9-171247). According to the process of platemaking using a plate precursor, since an image mask having the same function as that of an original image film is formed from the mask layer element by laser irradiation based on image data, the process is called a “mask CTP (Computer-To-Plate) method”. In this process, an original image film is not required, but platemaking treatment thereafter includes a step of performing light exposure with ultraviolet light via an image mask to develop and remove an uncured area, and there is room for improvement since development treatment is necessary.

As a method of manufacturing a plate without using a developing step, many so-called “direct engraving CTP methods” have been proposed in which a relief forming layer is directly engraved with a laser to manufacture a plate. The direct engraving CTP method is a method of forming recesses and projections, which are to be a relief, by engraving with a laser, and has an advantage in that, unlike a relief formation method using an original image film, a relief shape can be freely controlled. For this reason, when an image such as an outline character is formed, its region may be engraved deeper than other regions, or when a fine dot image is formed, engraving with a shoulder may be performed in view of resistance to a printing pressure.

For example, Japanese Patent No. 2846954 and Japanese Patent Application Laid-Open (JP-A) Nos. 11-338139 and 11-170718 disclose flexographic printing plate precursors suitable for laser engraving, and flexographic printing plates made by laser engraving. In these documents, as a binder, an elastic rubber is mixed with a monomer, and the mixture is cured by thermal polymerization or photopolymerization, followed by laser engraving, thus producing a flexographic printing plate.

However, a high amount of energy is necessary to form a relief pattern having resistance against printing pressure on a relief forming layer having a certain thickness, and laser engraving proceeds slowly on the layer. Therefore, the method is inferior in productivity to a method including image formation through a mask.

For this reason, attempts to improve the sensitivity of a relief plate precursor are being made. For example, a flexographic printing plate precursor for laser engraving including a foamed elastomer has been proposed (see, e.g., JP-A No. 2002-357907). In this technique, improvement in engraving sensitivity is made by using a foamed material having a low density in a relief forming layer, but since it is a material having a low density, the strength necessary for a printing plate is insufficient, and print durability is remarkably deteriorated.

For example, Japanese Patent No. 2846954 proposes a laser engravable flexographic printing plate containing a mechanically, photochemically, or thermochemically reinforced elastomer. However, this technique cannot provide sufficient engraving sensitivity.

As described above, various techniques are proposed regarding resin compositions suitable for the formation of relief forming layers of relief printing plate precursors for laser engraving. However, there is still no resin composition which forms a film having good physical properties, imparts good printing durability to a printing plate having a relief forming layer made of the resin composition, and achieves high engraving sensitivity in laser engraving.

### SUMMARY OF THE INVENTION

According to one aspect of the present invention, a relief printing plate precursor for laser engraving is provided which has high printing durability, and high engraving sensitivity. Also, a method for manufacturing a relief printing plate using the relief printing plate precursor, and a relief printing plate obtained by the manufacture method are provided.

According to another aspect of the invention, a resin composition for laser engraving is provided which forms a film having good physical properties, imparts good printing durability to a printing plate having a relief forming layer made of the resin composition, and achieves high laser engraving sensitivity.

According to a first aspect of the invention, a relief printing plate precursor for laser engraving has a relief forming layer formed by crosslinking a resin composition for laser engraving containing a compound (A) having at least two isocyanate groups in its molecule, and a polymer compound (B) having at least one substituent selected from the group consisting of a hydroxyl group and —NHR,

wherein R represents a hydrogen atom, a linear alkyl group, a branched alkyl group, an alkenyl group, an alkynyl group, a cycloalkyl group, an alkoxy group, an aryl group, or a heterocyclic group.

### DETAILED DESCRIPTION OF THE INVENTION

The relief printing plate precursor for laser engraving, the resin composition for laser engraving, the relief printing plate, and the method for manufacturing a relief printing plate according to the invention are further described below in detail.

Relief Printing Plate Precursor for Laser Engraving

A relief printing plate precursor for laser engraving according to an exemplary embodiment of the invention includes a relief forming layer formed by crosslinking a resin composition for laser engraving containing a compound (A) having at least two isocyanate groups in its molecule, and a polymer compound (B) having at least one substituent selected from the group consisting of a hydroxyl group and —NHR, in which R represents a hydrogen atom, a linear or branched alkyl group, an alkenyl group, an alkynyl group, a cycloalkyl group, an alkoxy group, an aryl group, or a heterocyclic group.

In other words, the relief printing plate precursor for laser engraving of the invention includes a relief forming layer containing at least a crosslinked product of the resin composition for laser engraving of the invention, which will be further described later, more specifically, a crosslinked product of at least a compound (A) having at least two isocyanate groups in its molecule, and a polymer compound (B) having at least one substituent selected from the group consisting of a hydroxyl group and —NHR.

Firstly, the components of the resin composition for laser engraving according to the invention used for the formation of a relief forming layer are described below.

Resin Composition for Laser Engraving

The resin composition for laser engraving according to one exemplary embodiment of the invention includes a compound (A) having at least two isocyanate groups in its molecule, and a polymer compound (B) having at least one substituent selected from the group consisting of a hydroxyl group and —NHR.

Compound (A) Having at Least Two Isocyanate Groups in its Molecule

The resin composition for laser engraving of the invention includes a compound (A) having at least two isocyanate groups in its molecule (hereinafter may be referred to as “polyfunctional isocyanate compound”).

The polyfunctional isocyanate compound (A) used in the invention has two or more isocyanate groups in its molecule. For the formation of a three-dimensionally crosslinked structure, the number of isocyanate groups is preferably from 2 to 10, more preferably from 2 to 6, and even more preferably from 2 to 4.

The polyfunctional isocyanate is further described below.

Examples of compounds having two isocyanate groups in its molecule include m-phenylene diisocyanate, p-phenylene diisocyanate, 2,6-isocyanate, 2,4-tolylene diisocyanate, naphthalene-1,4-diisocyanate, diphenylmethane-4,4′-diisocyanate, 3,3′-dimethoxy-biphenyl diisocyanate, 3,3′-dimethyldiphenylmethane-4,4′-diisocyanate, xylylene-1,4-diisocyanate, xylylene-1,3-diisocyanate, 4-chloroxylylene-1,3-diisocyanate, 2-methylxylylene-1,3-diisocyanate, 4,4′-diphenylpropane diisocyanate,

4,4′-diphenylhexafluoropropane diisocyanate, trimethylene diisocyanate, hexamethylene diisocyanate, propylene-1,2-isocyanate, butylene-1,2-diisocyanate, cyclohexylene-1,2-diisocyanate, cyclohexylene-1,3-diisocyanate, cyclohexylene-1,4-diisocyanate, dicyclohexylmethane-4,4′-diisocyanate, 1,4-bis(isocyanate methyl)cyclohexane, 1,3-bis(isocyanate methyl)cyclohexane, isophorone diisocyanate, and lysine diisocyanate. Other examples include products formed by addition reaction between the bifunctional isocyanate compounds and bifunctional alcohols or phenols such as ethylene glycols or bisphenols.

Higher-functional isocyanate compounds may also be used. Examples of the polyfunctional isocyanate compounds include biuret or isocyanurate trimers composed mainly of the bifunctional isocyanate compounds; polyfunctional adducts between polyols such as trimethylolpropane and the bifunctional isocyanate compounds; formalin condensates of benzene isocyanate; polymerized isocyanate compounds having polymerizable groups, such as methacryloyloxyethyl isocyanate; and lysine triisocyanate.

Among them, biuret or isocyanurate trimers composed mainly of xylene diisocyanate and hydrogenated derivatives thereof, isocyanate, tolylene diisocyanate and hydrogenated derivatives thereof, and polyfunctional adducts between trimethylolpropane and these diisocyanates or hydrogenated derivatives thereof are particularly preferred. These compounds are described in “Polyurethane Jushi Handbook” (edited by Keiji Iwata, The Nikkan Kogyo Shimbun, Ltd. (1987)).

Among these compounds, 2,4-tolylene diisocyanate, 2,6-tolylene diisocyanate, xylylene-1,4-diisocyanate, xylylene-1,3-diisocyanate, an adduct between trimethylolpropane and xylylene-1,4-diisocyanate or xylylene-1,3-diisocyanate are preferred, and xylylene-1,4-diisocyanate, xylylene-1,3-diisocyanate, and an adduct between trimethylolpropane and xylylene-1,4-diisocyanate or xylylene-1,3-diisocyanate are particularly preferred.

From the viewpoint of engraving sensitivity, the polyfunctional isocyanate compound (A) preferably has, in a moiety that links two isocyanate groups, a hetero atom such as nitrogen, oxygen, or sulfur, and more preferably has a carbon-sulfur bond.

More specifically, a linking group having a carbon-sulfur bond is preferably at least one selected from —C—S—, —C—SS—, —NH(C═S)O—, —NH(C═O)S—, —NH(C═S)S—, and —C—SO²—. Among them, for the improvement of engraving sensitivity, —C—SS—, —NH(C═S)O—, —NH(C═O)S—, and —NH(C═S)S— are more preferred, and —C—SS— and —NH(C═O)S— are most preferred.

In a preferable embodiment of the invention, the polyfunctional isocyanate compound (A) has a carbon-sulfur bond in a moiety that links two isocyanate groups. The number of sulfur atoms contained in one molecule is at least one and may be selected as appropriate according to the intended use. From the viewpoint of the balance between engraving sensitivity and solubility in a coating solvent, the number of sulfur atoms contained in the polyfunctional isocyanate compound is preferably from 1 to 10, more preferably from 1 to 5, and even more preferably 1 or 2.

The sulfur-containing isocyanate compound containing sulfur atom(s) in its molecule may be synthesized by the addition reaction between a polyfunctional isocyanate and a sulfur-containing polyfunctional alcohol, a sulfur-containing polyfunctional amine, or a polyfunctional thiol.

Alternatively, a polyfunctional isocyanate having a polyoxyalkylene chain is preferable. The polyoxyalkylene chain is preferably a polyoxyethylene chain or a polyoxypropylene chain.

Specific examples of the polyfunctional isocyanate compound (A) are shown below, but the invention will not limited to these examples.

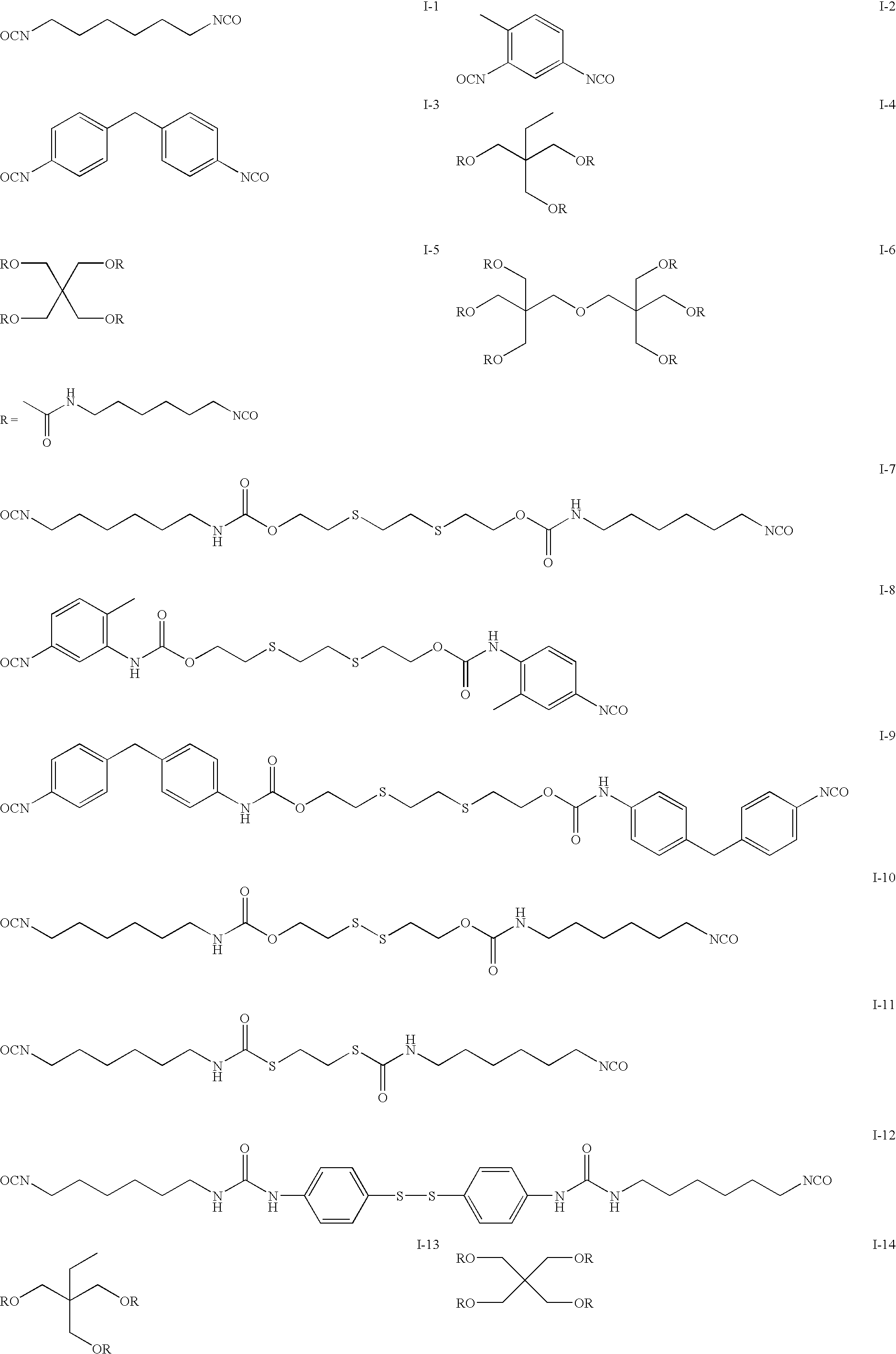

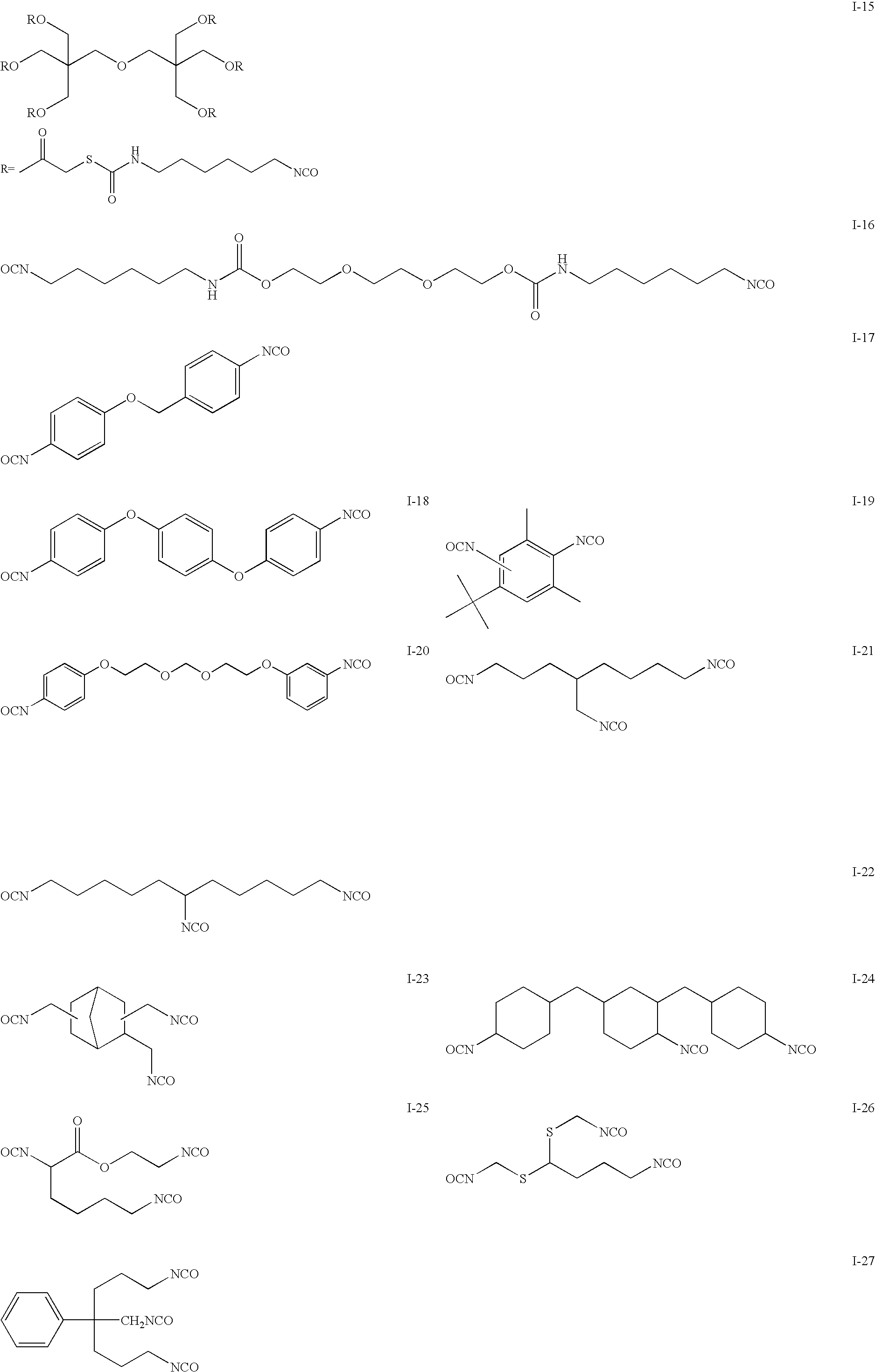

Among the specific examples of the polyfunctional isocyanate compound (A), from the viewpoint of improvement of engraving sensitivity, the compounds I-7 to I-15 are preferred, and the compounds I-7, I-8, I-10, I-11, I-12, and I-13 are more preferred, and the compounds I-7, I-10, and I-11 are even more preferred.

The molecular weight of the polyfunctional isocyanate compound (A) is preferably from 100 to 5000, and more preferably from 150 to 3000, from the viewpoint of flexibility of the film to be formed.

The amount of the polyfunctional isocyanate compound (A) to be added is preferably from 0.1% to 80% by mass, more preferably from 1% to 40% by mass, and even more preferably from 5% to 30% by mass, with respect to the total solid content of the resin composition for laser engraving.

Polymer Compound (B) Having at Least One Substituent Selected from the Group Consisting of a Hydroxyl Group and —NHR

The resin composition for laser engraving of the invention includes a polymer compound (B) having at least one substituent selected from the group consisting of a hydroxyl group and —NHR (hereinafter may be referred to as specific polymer compound). The symbol R represents a hydrogen atom, a linear or branched alkyl group, an alkenyl group, an alkynyl group, a cycloalkyl group, an alkoxy group, an aryl group, or a heterocyclic group.

Examples of the linear or branched alkyl group represented by the symbol R in the substituent —NHR include alkyl groups having 1 to 20 carbon atoms. Examples of the alkenyl group represented by the symbol R include alkenyl groups having 2 to 20 carbon atoms. Examples of the alkynyl group represented by the symbol R include alkynyl groups having 2 to 20 carbon atoms.

Examples of the cycloalkyl group, alkoxy group, aryl group represent by the symbol R in the substituent —NHR include cycloalkyl groups having 2 to 7 carbon atoms, alkoxy groups having 1 to 20 carbon atoms, and aryl groups having 2 to 14 carbon atoms, respectively.

The symbol R in the substituent —NHR preferably represents a hydrogen atom, a linear or branched alkyl group having 1 to 5 carbon atoms, an alkoxy group having 1 to 5 carbon atoms, or an aryl group having 3 to 6 carbon atoms.

The polymer backbone of the specific polymer compound (B) is not particularly limited, and examples thereof include polyether, polyester, polyamide, polyurea, polyurethane, polysiloxane, acrylic resins, epoxy resins, and polymerized vinyl monomers (hereinafter referred to as vinyl polymers). In the invention, the term “acrylic resin” refers to polymers containing at least one (meth)acrylic monomer as a polymerization component.

In the specific polymer compound (B), the site of substitution with the hydroxyl group or —NHR is not particularly limited. For example, the specific polymer compound (B) may have any of these groups at the end(s) of its main chain or in side chains. From the viewpoints of reactivity and synthetic easiness, the specific polymer compound (B) preferably has any of these groups in the side chain.

The specific polymer compound (B) in the invention may be the above-described polymer having at least one of a hydroxyl group and —NHR at the end(s) of the main chain or in the side chain of the backbone. The specific polymer compound particularly preferably has a hydroxyl group.

Other preferred examples of the specific polymer compound (B) include those obtained by terminal hydroxylation of polymers such as polybutadiene, polyisoprene, and polyolefin. These polymers are commercially available, and examples thereof include POLY BD (registered trademark), POLY IP (registered trademark), EPOL (registered trademark), and KRASOL series (all manufactured by Idemitsu Kosan Co., Ltd).

The specific polymer compound (B) having at least one substituent selected from the group consisting of a hydroxyl group and —NHR is preferably an acrylic resin, an epoxy resin, a vinyl polymer containing a hydroxyethylene unit, polyester, or polyurethane. In particular, from the viewpoints of rinsability and printing durability when formed into a relief forming layer, the specific polymer compound (B) is more preferably at least one selected from the group consisting of acrylic resins and polyvinyl acetal, and even more preferably polyvinyl butyral.

Among those useful as the specific polymer compound (B) according to the invention, the polymer compound having a hydroxyl group in its side chain is described below.

Preferred examples of the polymer compounds having a hydroxyl group in its side chain include acrylic resins having a hydroxyl group in its side chain, epoxy resins having a hydroxyl group in its side chain, polyesters having a hydroxyl group in its side chain, and vinyl polymers having a hydroxyl group in its side chain.

Examples of acrylic monomers used for the synthesis of the acrylic resins having a hydroxyl group in its side chain include (meth)acrylates, crotonates, and (meth)acrylamides, which preferably have a hydroxyl group in its molecule. Specific examples of the monomers include 2-hydroxyethyl(meth)acrylate, 2-hydroxypropyl(meth)acrylate, and 4-hydroxybutyl(meth)acrylate. Copolymers prepared by the polymerization of these monomers with known (meth)acrylic monomers or vinyl monomers are preferred herein.

The acrylic resins may contain, as a copolymerization component, additional acrylic monomers other than the acrylic monomers having a hydroxyl group. Examples of the additional acrylic monomers include (meth)acrylates such as methyl(meth)acrylate, ethyl(meth)acrylate, n-propyl(meth)acrylate, isopropyl(meth)acrylate, n-butyl(meth)acrylate, isobutyl(meth)acrylate, tert-butyl(meth)acrylate, n-hexyl(meth)acrylate, 2-ethylhexyl(meth)acrylate, acetoxyethyl(meth)acrylate, phenyl(meth)acrylate, 2-methoxyethyl(meth)acrylate, 2-ethoxyethyl(meth)acrylate, 2-(2-methoxyethoxy)ethyl(meth)acrylate, cyclohexyl(meth)acrylate, benzyl(meth)acrylate, diethylene glycol monomethyl ether(meth)acrylate, diethylene glycol monoethyl ether(meth)acrylate, diethylene glycol monophenyl ether(meth)acrylate, triethylene glycol monomethyl ether(meth)acrylate, triethylene glycol monoethyl ether(meth)acrylate, dipropylene glycol monomethyl ether(meth)acrylate, polyethylene glycol monomethyl ether(meth)acrylate, polypropylene glycol monomethyl ether(meth)acrylate, monomethyl ether(meth)acrylate of the copolymer of ethylene glycol and propylene glycol, N,N-dimethylaminoethyl(meth)acrylate, N,N-diethylaminoethyl(meth)acrylate, and N,N-dimethylaminopropyl(meth)acrylate.

Other preferred examples include modified acrylic resins composed of acrylic monomers having an urethane group or an urea group.

Among them, from the viewpoint of resistance against water-based inks, alkyl(meth)acrylates such as lauryl(meth)acrylate, and (meth)acrylates having an aliphatic cyclic structure, such as t-butyl cyclohexyl methacrylate, are particularly preferred.

Specific examples of epoxy resins having a hydroxyl group in its side chain include epoxy resins prepared by the polymerization of adducts between bisphenol A and epichlorohydrin, which are used as starting monomers.

The epoxy resins preferably have a weight average molecular weight of 800 to 200,000, and a number average molecular weight of 400 to 60,000.

Preferred examples of polyesters include polyesters composed of hydroxycarboxylic acid units, such as polylactic acid. Specifically, these polyesters are preferably selected from the group consisting of polyhydroxy alkanoate (PHA), lactic acid polymers, polyglycolic acid (PGA), polycaprolactone (PCL), poly(butylene succinic acid), and derivatives and mixtures thereof.

Preferred examples of vinyl polymers having a hydroxyethylene unit include polyvinyl alcohol (PVA) and derivatives thereof.

Examples of PVA derivatives include acid-modified PVA prepared by converting at least a portion of the hydroxyl groups of the hydroxyethylene unit into acid groups such as carboxyl groups; modified PVA prepared by converting a part of the hydroxyl groups into (meth)acryloyl groups; modified PVA prepared by converting at least a portion of the hydroxyl groups into amino groups; modified PVA prepared by introducing ethylene glycol, propylene glycol, or a multimer thereof into at least a portion of the hydroxyl groups; and polyvinyl acetal prepared by treating polyvinyl alcohol with aldehyde. Among them, the polyvinyl acetal is particularly preferred.

Polyvinyl acetal is a compound prepared by cyclic acetalization of a polyvinyl alcohol, which is prepared by saponification of a polyvinyl acetate.

The acetal content of the polyvinyl acetal (the molar percentage of the vinyl alcohol unit to be acetalized, with the proviso that the total number of moles of the vinyl acetate monomer to be polymerized is 100%) is preferably from 30% to 90%, more preferably from 50% to 85%, and particularly preferably from 55% to 78%.

The proportion of the vinyl alcohol unit in the polyvinyl acetal with respect to the total number of moles of the vinyl acetate monomer to be polymerized is preferably from 10 mol % to 70 mol %, more preferably from 15 mol % to 50 mol %, and particularly preferably from 22 mol % to 45 mol %.

The polyvinyl acetal may further contain a vinyl acetate unit, and the proportion thereof is preferably from 0.01 mol % to 20 mol %, and more preferably from 0.1 mol % to 10 mol %. The polyvinyl acetal may further contain other comonomers.

Examples of the polyvinyl acetal include polyvinyl butyral, polyvinyl propylal, polyvinyl ethylal, and polyvinyl methylal. Among them, polyvinyl butyral is a preferred PVA derivative.

Preferred examples of the aldehyde used for acetal treatment include acetaldehyde and butyl aldehyde, because they are easy to handle.

Hereinafter, a description is given to polyvinyl butyral as a preferable example of polyvinyl acetal; however, the present invention is not limited thereto.

Examples of polyvinyl butyral derivatives are shown below, and a polyvinyl butyral includes any of the following structures.

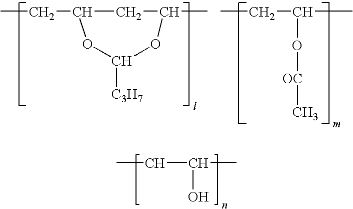

The polyvinyl butyral derivatives may be a commercial product, and preferred examples thereof include, from the viewpoint of solubility in alcohols (specifically ethanol), S-LEC B series and S-LEC K series (specifically S-LEC KS) (trade names, manufactured by Sekisui Chemical Co., Ltd.) and DENKA BUTYRAL series (trade name, manufactured by Denki Kagaku Kogyo Kabushiki Kaisha). Even more preferred examples include, from the viewpoint of solubility in alcohols (specifically ethanol), “S-LEC B” series (manufactured by Sekisui Chemical Co., Ltd.) and “DENKA BUTYRAL” series (manufactured by Denki Kagaku Kogyo Kabushiki Kaisha). Particularly preferred examples of the commercial products are described below with the numbers of “1”, “m”, and “n” shown in the above structural formula and molecular weights: “S-LEC B” series (manufactured by Sekisui Chemical Co., Ltd.) such as “BL-1” (1=61, m=3, n=36; Mw=19,000), “BL-1H” (1=67, m=3, n=30; Mw=20,000), “BL-2” (1=61, m=3, n=36; Mw=about 27,000), “BL-5” (1=75, m=4, n=21; Mw=32,000), “BL-S” (1=74, m=4, n=22; Mw=23,000), “BM-S” (1=73, m=5, n=22; Mw=53,000), and “BH-S” (1=73, m=5, n=22; Mw=66,000), and “DENKA BUTYRAL” series (manufactured by Denki Kagaku Kogyo Kabushiki Kaisha) such as “#3000-1” (1=71, m=1, n=28; Mw 74,000), “#3000-2” (1=71, m=1, n=28; Mw=90,000), “#3000-4” (1=71, m=1, n=28; Mw=117,000), “#4000-2” (1=71, m=1, n=28; Mw=152,000), “#6000-C” (1=64, m=1, n=35; Mw=308,000), “#6000-EP” (1=56, m=15, n=29; Mw=381,000), “#6000-CS” (1=74, m=1, n=25; Mw=322,000), and “#6000-AS” (1=73, m=1, n=26; Mw=242,000).

Alternatively, the specific polymer compound (B) having a hydroxyl group in its side chain may be a novolac resin prepared by condensation of a phenol and an aldehyde under acidic conditions.

Preferred examples of the novolac resin include a novolac resin prepared from phenol and formaldehyde, a novolac resin prepared from m-cresol and formaldehyde, a novolac resin prepared from p-cresol and formaldehyde, a novolac resin prepared from o-cresol and formaldehyde, a novolac resin prepared from octyl phenol and formaldehyde, a novolac resin prepared from m-/p-mixture cresol and formaldehyde, and a novolac resin prepared from a phenol/cresol mixture (any of m-, p-, o-mixture, m-/p-mixture, m-/o-mixture, o-/p-mixture) and formaldehyde.

These novolac resins preferably have a weight average molecular weight of 800 to 200,000, and a number average molecular weight of 400 to 60,000.

In the invention, the hydroxyl group content of the specific polymer compound (B) according to any of the embodiments of the invention is preferably from 0.1 to 15 mmol/g, and more preferably from 0.5 to 7 mmol/g.

Next, among those useful as the specific polymer compound (B), the polymer having —NHR in its side chain is described below.

The polymer having —NHR in its side chain is preferably an acrylic resin. Preferred examples of the acrylic resin include a polymer having acrylamide as a polymerization component, and a polymer prepared by aminoalkylating carboxyl groups of an acrylic acid copolymer. These polymers are commercially available. Examples of commercial products include POLYMENT series (registered trademark, manufactured by Nippon Shokubai Co., Ltd.).

In the invention, the —NHR group content of the specific polymer compound (B) according to any of the embodiments of the invention is preferably from 0.1 to 15 mmol/g, and more preferably from 0.5 to 7 mmol/g.

In the resin composition for laser engraving of the invention, the polyfunctional isocyanate group of the polyfunctional isocyanate (A) reacts with the hydroxyl group or —NHR group of the specific polymer compound (B), whereby the molecules of the specific polymer compound (B) are three-dimensionally crosslinked by the polyfunctional isocyanate group. Therefore, the film thus formed has good physical properties. When the resin composition is formed into a relief forming layer, the printing plate having the relief forming layer has good ink transfer properties and printing durability.

The urethane bond contributing to the three-dimensionally crosslinked structure formed by the reaction between the polyfunctional isocyanate group of the polyfunctional isocyanate (A) and the hydroxyl group or —NHR group of the specific polymer compound (B) has a relatively weak bonding strength and is readily cleaved by laser engraving. This is likely the reason for the improvement of engraving sensitivity.

It is particularly preferred that the specific polymer compound (B) has a glass transition temperature (Tg) higher than 20° C. when used in combination with the below-described photothermal converting agent (E) that absorbs light in the wavelength range of 700 to 1300 nm, which is a preferred additional component of the resin composition for laser engraving forming the relief forming layer in the invention, thereby improving engraving sensitivity. The binder polymer having the above-described glass transition temperature is hereinafter referred to as “non-elastomer”. Commonly, an elastomer is scientifically defined as a polymer whose glass transition temperature is equal to or below ordinary temperature (20° C.) (Kagaku Daijiten, Second Edition, edited by Foundation for Advancement of International Science, Maruzen Co., Ltd., page 154). Accordingly, a non-elastomer refers to a polymer whose glass transition temperature is higher than ordinary temperature.

The upper limit of the glass transition temperature of the specific polymer compound (B) is not particularly limited, but is preferably 200° C. or lower, more preferably from 20° C. to 200° C., and even more preferably from 25° C. to 120° C., from the viewpoint of handleability.

When a polymer having a glass transition temperature higher than 20° C. is used as the specific polymer compound (B), the specific polymer compound (B) is in a glassy state at normal temperature, and its thermal molecular motion is markedly slower than in a rubbery state. During laser irradiation for laser engraving, heat yielded by a laser and heat generated by the photothermal converting agent (E), which is optionally added, are transferred to the specific polymer compound (B) in adjacent areas, and the specific polymer compound (B) is thermally decomposed to be dissipated, and thus is engraved to form a recess.

According to a preferred embodiment of the invention, when the photothermal converting agent (E) is used in combination with the specific polymer compound (B) having slow thermal molecular motion, heat transfer to the specific polymer compound (B) and thermal decomposition of the specific polymer compound (B) are believed to occur effectively. This is likely the reason for the further improvement in engraving sensitivity.

In the invention, the weight average molecular weight of the specific polymer compound (B), in terms of polystyrene as measured by Gel Permeation Chromatography (GPC), is preferably from 5,000 to 500,000, more preferably from 10,000 to 400,000, and even more preferably from 15,000 to 300,000. When the weight average molecular weight is 5,000 or more, the single resin favorably holds its shape, and when 500,000 or less, the polymer compound is readily soluble in a solvent such as water, and thus is suitable for the preparation of a resin composition for laser engraving.

As described above, in consideration of the physical properties according to the intended use of the resin composition for laser engraving, an appropriate binder polymer is selected and used in combination with one or more kinds of the specific polymer compound (B).

The amount of the specific polymer compound (B) according to the invention may be from 5% to 80% by mass, preferably from 15% to 75% by mass, and more preferably from 20% to 65% by mass, with respect to the total solid content of the resin composition for laser engraving.

For example, when the resin composition for laser engraving of the invention is formed into a relief forming layer of a relief printing plate precursor, the addition of the binder polymer in an amount of 15% by mass or more provides printing durability sufficient for the formed relief printing plate to serve as a printing plate, and the addition of the binder polymer in an amount of 75% by mass or less provides sufficient flexibility for the relief printing plate to serve as a flexographic printing plate without causing the deficiency of other components.

Solvent

The solvent used for the preparation of the resin composition for laser engraving of the invention is preferably composed mainly of an aprotic organic solvent, from the viewpoint of accelerating the reaction between the polyfunctional isocyanate (A) and the specific polymer compound (B). More specifically, it is preferred that an aprotic organic solvent and a protonic organic solvent be used at a ratio of from 100/0 to 50/50 (mass ratio), more preferably from 100/0 to 70/30, and particularly preferably from 100/0 to 90/10.

Preferred examples of the aprotic organic solvent include acetonitrile, tetrahydrofuran, dioxane, toluene, propylene glycol monomethyl ether acetate, methyl ethyl ketone, acetone, methyl isobutyl ketone, ethyl acetate, butyl acetate, ethyl lactate, N,N-dimethylacetamide, N-methylpyrrolidone, and dimethylsulfoxide.

Preferred examples of the protonic organic solvent include methanol, ethanol, 1-propanol, 2-propanol, 1-butanol, 1-methoxy-2-propanol, ethylene glycol, diethylene glycol, and 1,3-propanediol.

Catalyst

The addition reaction of the polyfunctional isocyanate compound (A) to the hydroxyl group or —NHR of the specific polymer compound (B) is achieved by carrying out the reaction in an organic solvent at a reaction temperature of 20 to 100° C. for several hours to several ten hours. The reaction is preferably carried out in the presence of a catalyst, to increase the reaction speed.

The catalyst may be freely selected from common urethanation catalysts. Examples of the catalysts include basic catalysts, organometallic catalysts, and acid catalysts. From the viewpoint of catalytic activity, basic catalysts and organometallic catalysts are preferred.

Specific examples of basic catalysts include triethylamine, N,N-dimethylcyclohexylamine, N,N,N′,N′-tetramethylethylenediamine, N,N,N′,N′-tetramethylhexamethylenediamine, N,N,N′,N″,N″-pentamethyldiethylenetriamine, N,N,N′,N″,N″-pentamethyldipropylenetriamine, triethylenediamine, N-methyl-N′-(2-dimethylaminoethyl)piperazine, N-ethylmorpholine, 1,2-dimethylimidazole, dimethylethanolamine, dimethylaminoethoxyethanol, N,N,N′-trimethylaminoethylethanolamine, N-methyl-N′-(2-hydroxyethyl)piperazine, and bis(2-dimethylaminoethyl)ether.

Examples of the metals useful for the organometallic catalysts include alkali metals, alkaline earth metals, Group 14 metals such as tin and lead, Group 15 metals such as Bi, and other transition metals. Specific examples thereof include potassium acetate, potassium 2-ethyl hexanoate, calcium acetate, stannous octoate, dibutyltin dilaurate, dibutyltin mercaptide, lead octoate, bismuth-2-ethylhexanoate, bismuth neodecanoate, and bismuth oxycarbonate.

In addition, other examples of the catalyst to be used in the invention include P.

In the invention, the glass transition temperature (Tg) is measured as described below.

First, a resin for measurement is formed into a resin film (5 mm by 30 mm) to be measured for the glass transition temperature.

After the resin film for measurement is left at 25° C., 60% RH for 2 hours or more for moisture control, its viscoelasticity is measured using a dynamic viscoelasticity measurement apparatus (trade name: VIBRON DVA-225 manufactured by ITK Co., Ltd.) with an inter-chuck distance of 20 mm, temperature rising rate of 2° C./minute, temperature measuring range of 30° C. to 200° C., and a frequency of 1 Hz. The result is plotted with the storage elastic modulus as ordinate on a logarithmic scale, and the temperature (° C.) as abscissa on a linear scale.

In the graph, a sharp decrease of the storage elastic modulus, which can be observed when the storage elastic modulus of the solid region shifts to that of the glass transition region, is detected. The temperature corresponding to the sharp decrease is taken as the threshold, a straight line 1 is drawn along the plot in the solid region, and a straight line 2 is drawn along the plot in the glass transition region, and the point of intersection of the straight lines 1 and 2 is determined. This is the temperature at which the storage elastic modulus sharply decreases during temperature rising and the film starts softening. The temperature is regarded as the glass transition temperature Tg (dynamic viscoelasticity) of the crosslinked product.

In the resin composition for laser engraving of the invention, the mechanism of action achieved by the combination of the polyfunctional isocyanate (A) and the specific polymer compound (B) is still unknown, but is estimated as follows.

In the resin composition for laser engraving, the isocyanate group of the polyfunctional isocyanate (A) causes a reaction with the hydroxyl group (—OH) or —NHR of the coexisting specific polymer compound (B), which results in the three-dimensional crosslinking of the molecules of the specific polymer compound (B) by the polyfunctional isocyanate. Consequently, the film formed by the resin composition for laser engraving has improved physical properties (I) and resistance against plastic deformation. The improved film physical properties (I) imparts good printing durability to a printing plate having a relief forming layer made of the resin composition for laser engraving of the invention. According to a preferred embodiment of the invention, when hetero atoms are present in the polyfunctional isocyanate at the moiety that links the isocyanate groups, the hetero atoms contribute to the improvement of engraving sensitivity (II). The sensitivity improvement is significant when the hetero atoms contain a sulfur atom.

Specifically, it is likely that the molecules of the specific polymer compound (B) are directly crosslinked via the polyfunctional isocyanate (A), thereby forming a three-dimensionally crosslinked structure in the molecule and improving the film physical properties (I). Accordingly, when the resin composition for laser engraving of the invention is formed into a film to manufacture a relief forming layer, the relief layer thus obtained has good physical properties and resistance against plastic deformation even under repeated printing pressure over a long period of time, thus achieving improved printing durability.

The urethane bond contributing to the three-dimensionally crosslinked structure formed by the reaction between the polyfunctional isocyanate group of the polyfunctional isocyanate (A) and the hydroxyl group or —NHR group of the specific polymer compound (B) has a relatively weak bonding strength and is readily cleaved by laser engraving. This is likely the reason for the improvement of engraving sensitivity.

Further, when the polyfunctional isocyanate (A) has, in its molecule, a linking group containing a hetero atom linked to carbon, the carbon atom adjacent to the hetero atom has shared electrons localized near the hetero atom, so that the linking group is, in terms of energy, easily cleaved. As a result of this, thermal decomposition by laser engraving readily occurs, which results in the further improvement of engraving sensitivity (II).

As described above, the resin composition for laser engraving of the invention containing the polyfunctional isocyanate (A) and the specific polymer compound (B) exhibits various good properties during the preparation of and film formation by the composition, because a crosslinked structure is formed by the reaction between the polyfunctional isocyanate (A) and the hydroxyl group or —NHR of the specific polymer compound (B).

In the resin composition for laser engraving of the invention, the progress of the reaction between the polyfunctional isocyanate (A) and the specific polymer compound (B) and the formation of a crosslinked structure by the reaction may be generally confirmed by the change of the film properties. Specific examples of the methods are described below.

The crosslinked film may be identified by “solid ¹³C-NMR”.

The carbon atom directly linked to an OH group or —NHR of the specific polymer compound (B) changes its electrical environment before and after the reaction with the polyfunctional isocyanate (A), whereby the peak position of the carbon atom is shifted. The peak intensity of the carbon atom directly linked to an unreacted OH group or —NHR is compared with the peak intensity of the carbon atom directly linked to the OH group or —NHR of the polyfunctional isocyanate (A) before and after crosslinking, thus confirming the progress of the alcohol substitution and the approximate reaction rate. Since the extent of the shift of the peak position depends on the structure of the specific polymer compound (B), the peak shift is used as a relative index.

Alternatively, the progress of crosslinking may be checked by immersing the films before and after crosslinking and visually observing the appearance change of the films.

More specifically, the resin composition is formed into a film, the film is immersed in acetone at room temperature for 24 hours, and its appearance is visually observed. If the crosslinked structure is not formed or slightly formed, the film dissolves in acetone and is deformed to ruin the appearance, or the film dissolves so that no solid matter can be visually observed. On the other hand, if the film has a crosslinked structure, the film is insolubilized, and the film appearance remains the same as that before the immersion in acetone.

The resin composition for laser engraving of the invention may further include, in addition to the essential components (A) and (B) and the solvent, any of various compounds according to the intended use as long as the effect of the invention is not impaired.

### Additional Binder Polymer (B-2)

The resin composition for laser engraving of the invention may further include, in addition to the specific polymer compound (B), a known binder polymer other than the specific polymer compound (B), such as a binder polymer having no hydroxyl group or —NHR. The binder polymer is hereinafter referred to as an additional binder polymer (B-2).

The additional binder polymer (B-2) and the specific polymer compound (B) are main components of the resin composition for laser engraving. The additional binder polymer (B-2) may be appropriately selected from common polymer compounds other than the specific polymer compound (B), and may be used alone or in combination of two or more thereof. In particular, when the resin composition for laser engraving is used for a printing plate precursor, the additional binder polymer (B-2) must be selected in consideration of various properties such as laser engraving properties, ink receiving properties, and diffusivity of shavings.

The additional binder polymer may be selected from polystyrene resins, polyester resins, polysulfone resins, polyether sulfone resins, polycarbonate resins, acrylic resins, acetal resins, polycarbonate resins, rubbers, and thermoplastic elastomers.

For example, from the viewpoint of laser engraving sensitivity, the additional binder polymer is preferably a polymer having a partial structure which is thermally decomposable upon exposure or heating. Preferred examples of the polymer include those described JP-A No. 2008-163081, paragraph [0038]. When the formation of a soft and flexible film is desired, a soft resin or a thermoplastic elastomer is selected. They are described in detail in JP-A No. 2008-163081, paragraphs [0039] to [0040], for example. Further, when the resin composition for laser engraving is used to manufacture a relief forming layer of a relief printing plate precursor for laser engraving, the additional binder polymer preferably has affinity for water or alcohols, from the viewpoints of easiness of the preparation of the composition for forming a relief forming layer and the improvement in resistance of the relief printing plate against oil-based inks The hydrophilic polymer may be selected from those described in detail JP-A No. 2008-163081, paragraph [0041].

Polyesters composed of hydroxycarboxylic acid units such as polylactic acid are also preferred. Specifically, these polyesters are preferably selected from the group consisting of polyhydroxy alkanoate (PHA), lactic acid polymers, polyglycolic acid (PGA), polycaprolactone (PCL), poly(butylene succinic acid), and derivatives and mixtures thereof.

In addition, when the additional binder polymer is used for the improvement of strength through curing by heating or exposure to light, the binder polymer preferably has a carbon-carbon unsaturated bond in its molecule.

Examples of a polymer having a carbon-carbon unsaturated bond in its main chain include SB (polystyrene-polybutadiene), SBS (polystyrene-polybutadiene-polystyrene), SIS (polystyrene-polyisoprene-polystyrene), and SEBS (polystyrene-polyethylene/polybutylene-polystyrene).

A polymer having a carbon-carbon unsaturated bond in its side chain may be obtained by introducing a carbon-carbon unsaturated bond such as an allyl group, an acryloyl group, a methacryloyl group, a styryl group, or a vinyl ether group into the side chain of the backbone of the binder polymer useful in the invention. The introduction of a carbon-carbon unsaturated bond into the side chain of a binder polymer may be achieved by a known method such as (i) a method including polymerizing the polymer with a structural unit having a polymerizable group precursor, which has been formed by linking a polymerizable group with a protective group, and then desorbing the protective group thereby forming a polymerizable group, or (ii) a method including preparing a polymer compound having plural reactive groups such as a hydroxyl group, an amino group, an epoxy group, or a carboxyl group, and allowing the polymer to react with a compound having a carbon-carbon unsaturated bond and a group which reacts with the above reactive groups thereby introducing the carbon-carbon unsaturated bond into the polymer. These methods allow the control of the amount of the unsaturated bond and polymerizable group introduced into the polymer compound.

As described above, one or more binder polymers are selected in consideration of the properties suitable for the intended use of the relief printing plate.

The total amount of the binder polymer(s) [i.e., the total amount of the specific polymer compound (B) and the additional binder polymer (B-2)] may be from 5% to 95% by mass, preferably from 15% to 80% by mass, and more preferably from 20% to 65% by mass with reference to the total solid content of the resin composition for laser engraving.

For example, when the resin composition for laser engraving of the invention is formed into a relief forming layer of a relief printing plate precursor, the binder polymer contained in an amount of 5% by mass or more provides printing durability sufficient for the formed relief printing plate to serve as a printing plate, and the binder polymer contained in an amount of 80% by mass or less imparts sufficient flexibility for the relief printing plate used to serve as a flexographic printing plate without causing the deficiency of other components.

The resin composition for laser engraving used to form the relief forming layer of the relief printing plate precursor for laser engraving according to the invention includes the essential components, i.e., the polyfunctional isocyanate (A) and the specific polymer compound (B), and preferably further includes optional components such as a polymerizable compound (C), a polymerization initiator (D), a photothermal converting agent (E), and a plasticizer. These components are described below in detail.

Polymerizable Compound (C)

In the invention, in order to form a crosslinked structure in the relief forming layer, the resin composition for laser engraving preferably contains a polymerizable compound (C).

The polymerizable compound may be freely selected from compounds having at least one ethylenically-unsaturated double bond, preferably 2 or more ethylenically-unsaturated double bonds, and more preferably 2 to 6 ethylenically-unsaturated double bonds.

Examples of radical-polymerizable ethylenically-unsaturated compounds include unsaturated carboxylic acids and salts thereof, such as acrylic acid, methacrylic acid, itaconic acid, crotonic acid, isocrotonic acid, and maleic acid, anhydrides having an ethylenically-unsaturated group, (meth)acrylates, (meth)acrylamides, acrylonitrile, styrene, and various unsaturated polyesters, unsaturated polyethers, unsaturated polyamides, and unsaturated urethanes.

The term “(meth)acrylate” refer to an acrylate or a methacrylate, and the term “(meth)acrylamide” refers to an acrylamide or a methacrylamide.

Hereinafter, monofunctional monomers having one ethylenically-unsaturated double bond in its molecule and multifunctional monomers having two or more ethylenically-unsaturated bonds in its molecule, which are used as the polymerizable compounds (C), are further described.

Examples of the monofunctional monomers include acrylic acid derivatives such as methyl acrylate, ethyl acrylate, N-butyl acrylate, 2-ethylhexyl acrylate, 2-hydroxyethyl acrylate, butoxyethyl acrylate, carbitol acrylate, cyclohexyl acrylate, benzyl acrylate, N-methylol acrylamide, and epoxy acrylate; methacryl derivatives such as methyl methacrylate; N-vinyl compounds such as N-vinylpyrrolidone and N-vinylcaprolactam; and allyl compound derivatives such as allyl glycidyl ether, diallyl phthalate, and triallyl trimellitate.

Examples of the polyfunctional monomers include polyfunctional acrylates and methacrylates such as: ester compounds or amide compounds prepared from an unsaturated carboxylic acid and a polyhydric alcohol compound or a polyvalent amine compound, such as ethylene glycol diacrylate, triethylene glycol diacrylate, propylene glycol diacrylate, triethylene glycol dimethacrylate, 1,3-butanediol diitaconate, pentaerythritol dicrotonate, sorbitol tetramaleate, methylene bis-methacrylamide, and 1,6-hexamethylene bis-acrylamide; urethane acrylates as described in JP-A No. 51-37193; and polyester acrylates described in JP-A No. 48-64183, Japanese Patent Application Publication (JP-B) Nos. 49-43191 and 52-30490; and epoxy acrylates prepared by reaction between an epoxy resin and a (meth)acrylic acid. Other examples include commercial products described in Journal of the Adhesion Society of Japan, Vol. 20, No. 7, pages 300 to 308 (1984); “Kakyozai Handbook” edited by Shinzo Yamashita (1981, Taiseisha Ltd.); “UV EB Koka Handbook (Genryohen)” edited by Kiyoshi Kato (1985, Kobunshikankokai); “UV EV Kokagijutsuno Oyoto Shijo” edited by RadTech Japan, page 79, (1989, CMC Publishing Co., Ltd.); and “Polyester Jushi Handbook” written by Eiichiro Takiyama (1988, The Nikkan Kogyo Shimbun, Ltd.) and radically polymerizable or crosslinking monomers and oligomers known to those skilled in the art.

In the invention, the resin composition for laser engraving used to form the relief forming layer forms a crosslinked structure when formed into a film; therefore, the composition preferably includes a polyfunctional monomer. The polyfunctional monomer preferably has a molecular weight of 200 to 2,000.

In the invention, from the viewpoint of improving engraving sensitivity, the polymerizable compound (C) preferably includes a sulfur atom in its molecule.

In order to improve the engraving sensitivity, the polymerizable compound having a sulfur atom in its molecule is preferably a polymerizable compound having two or more ethylenically-unsaturated bonds and having a carbon-sulfur bond in a moiety that links two ethylenically-unsaturated bonds (hereinafter may be referred to as “sulfur-containing polyfunctional monomer”).

In the invention, examples of the functional group containing a carbon-sulfur bond in the sulfur-containing polyfunctional monomer include functional groups containing sulfide, disulfide, sulfoxide, sulfonyl, sulfonamide, thiocarbonyl, thiocarboxylic acid, dithiocarboxylic acid, sulfamic acid, thioamide, thiocarbamate, dithiocarbamate, or thiourea.

The number of sulfur atoms contained in one molecule of the sulfur-containing polyfunctional monomer is at least one and may be selected as appropriate according to the intended use. From the viewpoint of the balance between engraving sensitivity and solubility in a coating solvent, the number of sulfur atoms is preferably from 1 to 10, more preferably from 1 to 5, and even more preferably 1 or 2.

On the other hand, the number of ethylenically-unsaturated moieties in one molecule is at least two and may be selected as appropriate according to the intended use. From the viewpoint of flexibility of the crosslinked film, the number of ethylenically-unsaturated moieties is preferably from 2 to 10, more preferably from 2 to 6, and even more preferably from 2 to 4.

In the invention, the sulfur-containing polyfunctional monomer may be synthesized by a reaction between a sulfur atom-containing dicarboxylic acid and an epoxy group-containing (meth)acrylate, a reaction between a sulfur atom-containing diol and an isocyanate-containing (meth)acrylate, a reaction between a dithiol and an isocyanate-containing (meth)acrylate, a reaction between a diisothiocyanate and a hydroxyl group-containing (meth)acrylate, or a known esterification reaction. The sulfur-containing polyfunctional monomer may be a commercial product.

In the invention, the sulfur-containing polyfunctional monomer may be used alone, or in combination with a polyfunctional or monofunctional monomer having no sulfur atom in its molecule.

From the viewpoint of engraving sensitivity, it is preferred that the sulfur-containing polyfunctional monomer be used alone or in combination with a monofunctional ethylenic monomer, and it is more preferred that the sulfur-containing polyfunctional monomer be used in combination with a monofunctional ethylenic monomer.

In the relief forming layer, the total content of the polymerizable compound (C) such as a sulfur-containing polyfunctional monomer is, from the viewpoint of flexibility and brittleness of the crosslinked film, preferably from 10% to 60% by mass, and more preferably from 15% to 45% by mass, with respect to the nonvolatile components.

When the sulfur-containing polyfunctional monomer is used in combination with another polymerizable compound, the proportion of the sulfur-containing polyfunctional monomer is preferably 5% by mass or more, and more preferably 10% by mass or more, with respect to the total polymerizable compounds.

Polymerization Initiator (D)

The resin composition for laser engraving of the invention preferably further includes a polymerization initiator (D).

Any of polymerization initiators known to those skilled in the art may be used without limitation. Radical polymerization initiators suitable as the polymerization initiator are described below in detail, but the invention is not limited to these.

In the invention, preferred examples of the radical polymerization initiator include aromatic ketones (a), onium salt compounds (b), organic peroxides (c), thio compounds (d), hexaarylbiimidazole compounds (e), ketoxime ester compounds (f), borate compounds (g), azinium compounds (h), metallocene compounds (i), active ester compounds (j), compounds having a carbon-halogen bond (k), and azo compounds (l). Specific examples of (a) to (l) are listed below, but the invention is not limited to them.

In the invention, in order to achieve good engraving sensitivity and a good relief edge shape of a relief forming layer of a relief printing plate precursor, the organic peroxides (c) and azo compounds (l) are more preferred, and organic peroxides (c) are particularly preferred.

The aromatic ketones (a), onium salt compounds (b), thio compounds (d), hexaarylbiimidazole compounds (e), ketoxime ester compounds (f), borate compounds (g), azinium compounds (h), metallocene compounds (i), active ester compounds (j), and compounds having a carbon-halogen bond (k) are preferably selected from the compounds described in JP-A No. 2008-63554, paragraphs [0074] to [0118], for example.

The organic peroxides (c) and azo compounds (l) are preferably selected from the following compounds.

Organic Peroxides (c)

Examples of the organic peroxides (c) suitable as the radical polymerization initiator used in the invention include peroxyesters such as 3,3′4,4′-tetra-(tert-butylperoxycarbonyl)benzophenone, 3,3′4,4′-tetra-(tert-amylperoxycarbonyl)benzophenone, 3,3′4,4′-tetra-(tert-hexylperoxycarbonyl)benzophenone, 3,3′4,4′-tetra-(tert-octylperoxycarbonyl)benzophenone, 3,3′4,4′-tetra-(cumylperoxycarbonyl)benzophenone, 3,3′4,4′-tetra-(p-isopropylcumylperoxycarbonyl)benzophenone, and di-tert-butyl diperoxyisophthalate.

Azo Compounds (l)

Examples of the azo compounds (l) suitable as the radical polymerization initiator used in the invention include 2,2′-azobisisobutyronitrile, 2,2′-azobispropionitrile, 1,1′-azobis(cyclohexane-1-carbonitrile), 2,2′-azobis(2-methylbutyronitrile), 2,2′-azobis(2,4-dimethylvaleronitrile), 2,2′-azobis(4-methoxy-2,4-dimethylvaleronitrile), 4,4′-azobis(4-cyanovaleric acid), dimethyl 2,2′-azobisisobutyrate, 2,2′-azobis(2-methylpropionamide oxime), 2,2′-azobis[2-(2-imidazolin-2-yl) propane], 2,2′-azobis{2-methyl-N-[1,1-bis(hydroxymethyl)-2-hydroxyethyl]propionamide}, 2,2′-azobis[2-methyl-N-(2-hydroxyethyl)propionamide], 2,2′-azobis(N-butyl-2-methylpropionamide), 2,2′-azobis(N-cyclohexyl-2-methylpropionamide), 2,2′-azobis[N-(2-propenyl)-2-methylpropionamide], and 2,2′-azobis(2,4,4-trimethylpentane).

In the invention, the polymerization initiator (D) may be used alone or in combination of two or more thereof.

The amount of the polymerization initiator (D) is preferably from 0.01 to 10% by mass, and more preferably from 0.1 to 3% by mass, with respect to the total solid content in the relief forming layer.

Photothermal Converting Agent (E)

The resin composition for laser engraving according to the invention preferably further includes a photothermal converting agent (E). The photothermal converting agent likely absorbs laser light to generate heat, thereby promoting the thermal decomposition of the cured product of the resin composition for laser engraving of the invention. On that account, the photothermal converting agent used herein absorbs light of the laser wavelength used for engraving.

When the relief forming layer for laser engraving according to the invention is used for laser engraving using a laser emitting infrared light having a wavelength of 700 nm to 1300 nm (for example, YAG laser, semiconductor laser, fiber laser, or surface emitting laser) as the light source, the photothermal converting agent is preferably a compound having a maximum absorption wavelength in the range of 700 nm to 1300 nm.

In the invention, the photothermal converting agent may be selected from various dyes and pigments.

Among those useful as the photothermal converting agent, dyes may be commercially available dyes or known dyes such as those described in “Senryo Binran” (edited by The Society of Synthetic Organic Chemistry, Japan, published in 1970). Specific examples of the dyes include those having a maximum absorption wavelength in the range of 700 nm to 1300 nm, such as azo dyes, metallic complex salt azo dyes, pyrazolone azo dyes, naphthoquinone dyes, anthraquinone dyes, phthalocyanine dyes, carbonium dyes, diimmonium compounds, quinoneimine dyes, methine dyes, cyanine dyes, squarylium dyes, pyrylium salts, and metal thiolate complexes. In particular, cyanine dyes such as a heptamethine cyanine dye, oxonol dyes such as a pentamethine oxonol dye, and phthalocyanine dyes are preferred, and examples thereof include the dyes described in JP-A No. 2008-63554, paragraphs [0124] to [0137], for example.

Among the photothermal converting agents used in the invention, the pigment may be commercially available pigments or pigments described in Color Index (C.I.) Handbook, “Advanced Pigment Handbook” (edited by Japan Pigment Technique Association, published in 1977), “Advanced Pigment Application Technique” (CMC Publishing Co., Ltd., published in 1986), and “Printing Ink Technique” (CMC Publishing Co., Ltd., published in 1984).

Examples of the kind of the pigment include black pigments, yellow pigments, orange pigments, brown pigments, red pigments, purple pigments, blue pigments, green pigments, fluorescent pigments, metal powder pigments, and polymer binding coloring matters. Specific examples of the pigment include insoluble azo pigments, azo lake pigments, condensed azo pigments, chelate azo pigments, phthalocyanine pigments, anthraquinone pigments, perylene pigments, perynone pigments, thioindigo pigments, quinacridone pigments, dioxazine pigments, isoindolinone pigments, quinophthalone pigments, dyeing lake pigments, azine pigments, nitroso pigments, nitro pigments, natural pigments, fluorescent pigments, inorganic pigments, and carbon blacks. Among these pigments, carbon black is preferable.

Carbon black may be freely selected from those compliant with ASTM and various products for coloring, rubbers, dry batteries, and other applications, as long as it exhibits stable dispersibility in the composition. Examples of carbon black include furnace black, thermal black, channel black, lamp black, and acetylene black. In order to facilitate dispersion of a black coloring agent such as carbon black, the coloring agent may be preliminary dispersed in a nitrocellulose or a binder optionally with a dispersant to make color chips or a color paste. These chips and a paste are commercially available.

In the invention, from carbon blacks having a relatively low specific surface area and relatively low DBP absorption to finely-divided carbon black having a large specific surface area may be used. Examples of preferable carbon black include PRINTEX (registered trademark) U, PRINTEX (registered trademark) A, and SPEZIALSCHWARZ (registered trademark) 4 (manufactured by Degussa).

Carbon black useful in the invention is preferably conductive carbon black having a specific surface area of at least 150 m²/g and a DBP number of at least 150 ml/100 g, from the viewpoint of improving engraving sensitivity through the efficient transfer of the heat generated by photothermal conversion to the polymers around the carbon black.

The specific surface area is preferably at least 250 m²/g, and particularly preferably at least 500 m²/g. The DBP number is preferably at least 200 ml/100 g, and particularly preferably at least 250 ml/100 g. The above-described carbon black may be acidic or basic, and is preferably basic. Mixtures with different binders may be used herein.

Suitable conductive carbon blacks having a specific surface area of up to about 1,500 m²/g and a DBP number of up to about 550 ml/100 g are commercially available under the name of, for example, KETJENBLACK (registered trademark) EC300J, KETJENBLACK (registered trademark) EC600J (manufactured by from Akzo), PRINTEX (registered trademark) XE (manufactured by Degussa), BLACK PEARLS (registered trademark) 2000 (manufactured by Cabot), or KETJEN BLACK (trade name, manufactured by Lion Corporation).

The content of the photothermal converting agent (E) with respect to the total solid content in the relief forming layer is preferably from 0.01% to 20% by mass, more preferably from 0.05% to 10% by mass, and particularly preferably from 0.1% to 5% by mass, though the range markedly varies according to the molecular extinction coefficient specific to the molecule.

Other Additives

The resin composition for laser engraving of the invention preferably includes a plasticizer. The plasticizer softens the film formed by the resin composition for laser engraving, and must be highly compatible with the binder polymer.

Preferred examples of the plasticizer include dioctyl phthalates, didodecyl phthalates, polyethyleneglycols, polypropylene glycols (monool or diol), and polypropylene glycols (monool or diol).

The resin composition for laser engraving of the invention more preferably includes an additive for improving engraving sensitivity, such as nitrocellulose or a high thermal conductive substance. Since nitrocellulose is an autoreactive compound, it generates heat during laser engraving to help the thermal decomposition of the coexisting binder polymer such as a hydrophilic polymer. Accordingly, the engraving sensitivity is improved. The high thermal conductive substance is added for the purpose of helping heat transfer. Examples of thermal conductive substances include inorganic compounds such as metal particles, and organic compounds such as conductive polymers. The metal particles are preferably gold, silver, or copper fine particles having a particle size of micrometer to several nanometer order. The conductive polymer is particularly preferably a conjugated polymer such as polyaniline or polythiophene.

Further, the use of a co-sensitizer further improves the sensitivity during photocuring of the resin composition for laser engraving.

Further, in order to prevent the occurrence of unnecessary thermal polymerization of the polymerizable compound during manufacture or storage of the composition, it is preferred that a small amount of a thermal polymerization inhibitor be added.

In order to color the resin composition for laser engraving, a coloring agent such as a dye or pigment may be added. As a result of this, the visibility of image areas and suitability for image density measuring apparatuses are improved.

Further, in order to improve the properties of the cured film of the resin composition for laser engraving, known additives such as a filler may be added.

Since the resin composition for laser engraving of the invention provides high engraving sensitivity when used for laser engraving, it allows high-speed laser engraving, thereby reducing engraving time. The resin composition for laser engraving of the invention having the advantage may be freely used in a wide range of applications wherein resin moldings to be laser engraved are formed. For example, specific examples of the applications of the resin composition for laser engraving of the invention include, but not limited to, an image forming layer of an image forming material on which an image is formed by laser engraving, a relief forming layer of a printing plate precursor on which a raised relief is formed by laser engraving, an engraved printing plate, a stencil printing plate, and a stamp. The resin composition for laser engraving of the invention is particularly suitably used for an image forming layer of an image forming material on which an image is formed by laser engraving, and a relief forming layer of a relief printing plate precursor for laser engraving.

The relief printing plate precursor for laser engraving of the invention includes a relief forming layer formed by crosslinking the resin composition for laser engraving containing at least the components (A) and (B). The resin composition for laser engraving preferably further contains the polymerizable compound (C), polymerization initiator (D), and photothermal converting agent (E) as necessary. The relief forming layer is preferably formed on a support.

In the invention, the term “relief printing plate precursor for laser engraving” refers to a product including a support and, on the support, a crosslinkable relief forming layer composed of a resin composition for laser engraving, the relief forming layer having been cured by light or heat. The printing plate precursor is laser engraved, thereby manufacturing a “relief printing plate”.

As necessary, the relief printing plate precursor for laser engraving may further includes an adhesive layer between the support and the relief forming layer, and a slip coat layer and a protective film on the relief forming layer.

Relief Forming Layer

The relief forming layer is formed by crosslinking the resin composition for laser engraving of the invention. According to the invention, a crosslinkable relief forming layer is formed using a crosslinkable resin composition as the resin composition for laser engraving. The relief printing plate precursor for laser engraving of the invention preferably includes a relief forming layer which has a crosslinked structure composed of the polyfunctional isocyanate (A) and the specific binder polymer (B), and exhibits crosslinkability imparted by the polymerizable compound (C) and the polymerization initiator (D).

The procedure for manufacturing a relief printing plate using a relief printing plate precursor for laser engraving preferably includes crosslinking a relief forming layer thereby obtaining a relief printing plate precursor having a cured relief forming layer, followed by laser engraving the cured relief forming layer (hard relief forming layer) to form a relief layer, thus manufacturing a relief printing plate. The crosslinking of the relief forming layer prevents wear of the relief layer during printing, and provides a relief printing plate having a relief layer sharply engraved by laser engraving.

The relief forming layer may be formed by molding the resin composition for laser engraving, which contains the above-described components for forming a relief forming layer, in the form of a sheet or sleeve.

Support

The support used in the relief printing plate precursor for laser engraving is described below.

The material of the support used in the relief printing plate precursor for laser engraving is not particularly limited, and preferably has high dimensional stability. Examples of the material of the support include metals such as steel, stainless steel, and aluminium; plastic resins such as polyesters (for example, PET, PBT, and PAN) and polyvinyl chloride; synthetic rubbers such as styrene-butadiene rubber; and plastic resins (for example, epoxy resins and phenolic resins) reinforced with glass fibers. The support is preferably a polyethylene terephthalate (PET) film or a steel substrate. The form of the support depends on whether the form of the relief forming layer is a sheet or a sleeve. However, the printing plate precursor does not necessarily require a support because, in a relief printing plate precursor for laser engraving made by applying a crosslinkable resin composition for laser engraving, followed by curing the composition by light or heat applied from the backside (the side opposite to the surface to be laser engraved; the printing plate precursor may be cylindrical), the backside of the cured resin composition for laser engraving works as a support.

Adhesive Layer

An adhesive layer may be formed between the relief forming layer and the support, thereby enhancing the adhesive force between the layers. The material (adhesive) of the adhesive layer may be selected from those described in “Handbook of Adhesives”, edited by I. Skeist, Second edition (1977).

Protective Film and Slip Coat Layer

In order to prevent scratches and hollows on the relief forming layer, a protective film may be formed on the surface of the relief forming layer. The thickness of the protective film is preferably from 25 μm to 500 μm, and is more preferably from 50 μm to 200 μm. The protective film may be, for example, a polyester film such as polyethylene terephthalate (PET), or a polyolefin film such as polyethylene (PE) or polypropylene (PP). The film surface may be matted. When a protective film is formed on the relief forming layer, the protective film must be removable.

If the protective film is not removable or hard to adhere to the relief forming layer, a slip coat layer may be formed between the protective film and the relief forming layer. The material of the slip coat layer is preferably composed mainly of a water-soluble or water-dispersible resin with low adhesiveness, examples thereof including polyvinyl alcohols, polyvinyl acetates, partially saponified polyvinyl alcohols, hydroxyalkyl cellulose, alkyl cellulose, and polyamide resins.

Method for Manufacturing Relief Printing Plate Precursor for Laser Engraving

The method for manufacturing relief printing plate precursor for laser engraving is described below.

The procedure for forming a relief forming layer of a relief printing plate precursor for laser engraving is not particularly limited, and may include, for example, preparing a coating solution composition for forming a relief forming layer (containing the resin composition for laser engraving), removing the solvent from the coating solution composition for forming a relief forming layer, and then melt-extruding the composition on a support. Alternatively, the coating solution composition for forming a relief forming layer is cast on a support, and dried in an oven thereby removing the solvent from the coating solution composition.

Thereafter, as necessary, a protective film may be laminated on the relief forming layer. The lamination may be achieved by pressure bonding of the protective film with the relief forming layer using, for example, a hot calender roll, or by tightly attaching the protective film to the relief forming layer whose surface has been impregnated with a small amount of a solvent.

When a protective film is used, as a first step, a relief forming layer may be overlaid on a protective film, followed by laminating a support thereon.

When an adhesive layer is formed, a support covered with an adhesive layer may be used. When a slip coat layer is formed, a protective film covered with a slip coat layer may be used.

The coating solution composition for forming a relief forming layer may be prepared by, for example, dissolving the specific binder polymer (B) and optional components such as a photothermal converting agent and a plasticizer in an appropriate solvent, and then dissolving a polymerizable compound and a polymerization initiator, and finally adding the polyfunctional isocyanate (A). Since much of the solvent components must be removed during the manufacture of the relief printing plate precursor, the solvent is preferably a highly volatile low molecular ketone such as acetone, methyl ethyl ketone, or methyl isopropyl ketone, or a highly volatile low molecular ester such as ethyl acetate, butyl acetate, or propylene glycol monomethyl ether acetate. In addition, the total amount of the solvent is preferably minimized by, for example, controlling the temperature.

In the invention, the relief printing plate precursor for laser engraving includes a crosslinked relief forming layer as described above. The method for crosslinking the relief forming layer preferably includes crosslinking of the relief forming layer by irradiation with active light and/or heating (the below-described step (1) in the method of the invention for manufacturing a relief printing plate).

The thickness of the relief forming layer of the relief printing plate precursor for laser engraving is preferably from 0.05 mm to 10 mm, more preferably from 0.05 mm to 7 mm, and particularly preferably from 0.05 mm to 3 mm before and after crosslinking.

Relief Printing Plate and Manufacture Thereof

The method for manufacturing a relief printing plate of the invention using a relief printing plate precursor includes laser-engraving a relief forming layer of a relief printing plate precursor for laser engraving of the invention to form a relief layer.

It is preferable that the method for manufacturing a relief printing plate of the invention using a relief printing plate precursor includes: crosslinking the relief forming layer of the relief printing plate precursor for laser engraving of the invention by at least one of irradiation with active light and heating (hereinafter appropriately referred to as “step (1)”); and laser-engraving the crosslinked relief forming layer to form a relief layer (hereinafter appropriately referred to as “step (2)”).

According to the method for manufacturing a relief printing plate of the invention using a relief printing plate precursor, a relief printing plate of the invention including a support having thereon a relief layer is produced.

Step (1)

As described above, the relief printing plate precursor for laser engraving of the invention has at least a relief forming layer which has been cured by crosslinking. In order to form such relief forming layer, it is preferred that the relief forming layer of the relief printing plate precursor for laser engraving of the invention be crosslinked by irradiation with active light and/or by heating.

Irradiation with active light is generally performed on a whole surface of the relief forming layer. Examples of active light include visible light, ultraviolet light and electron beam, and ultraviolet light is most general. If a support side of the relief forming layer is a back side, it is enough that only a front side is irradiated with active light, but when the support is a transparent film through which active light transmits, it is preferable that active light is irradiated also from a back side. Irradiation from a front side, when there is a protective film, may be performed while the protective film is provided, or irradiation may be performed after peeling of the protective film. Since polymerization inhibition may occur in the presence of oxygen, active light may be irradiated after the relief forming layer is covered with a vinyl chloride sheet, and the system is evacuated.

When the relief forming layer contains a thermal polymerization initiator (the photopolymerization initiator may become the thermal polymerization initiator), the relief forming layer may be crosslinked by heating the relief printing plate precursor for laser engraving (step of crosslinking by heat). The heating may be performed by, for example, a method of heating the printing plate precursor in a hot air oven or a far infrared oven for a predetermined time, or a method of contacting the printing plate precursor with a heated roll for a predetermined time.

In the step (1), the relief forming layer is crosslinked preferably by heating from the viewpoint of uniformly curing (crosslinking) the relief forming layer from the surface to the inside.

The crosslinking of the relief forming layer gives two advantages: a sharp relief is formed by laser engraving; and shavings generated during laser engraving have low adhesiveness.

Step (2)

In the method for manufacturing a relief printing plate of the invention, the step (1) is followed by the step (2) in which the crosslinked relief forming layer is laser engraved to form a relief layer. According to the method for manufacturing a relief printing plate of the invention, the relief printing plate of the invention including a support having thereon a relief layer is produced.

In the step (2), the relief forming layer crosslinked in the step (1) is laser engraved to form a relief layer. More specifically, the crosslinked relief forming layer is engraved by irradiation with laser light corresponding to the image to be formed, thus forming a relief layer. According to a preferred procedure, the relief forming layer is subjected to scanning laser irradiation with the laser head controlled by a computer on the basis of the digital data of the image to be formed.

In the step (2), the use of an infrared laser is preferred. Upon irradiation with an infrared laser, molecules in the relief forming layer vibrate to generate heat. When a high power laser such as a CO₂ laser or a YAG laser is used as the infrared laser, high amounts of heat generate in the portion irradiated with the laser light, whereby the molecules in the relief forming layer are cleaved or ionized to be selectively removed, thus achieving engraving. One of the advantages of laser engraving is that the engraved depth can be adjusted, which allows three-dimensional control of the structure. For example, the areas to be printed with fine dots are engraved shallowly or with a slope thereby preventing the relief from being flattened by the printing pressure, and the grooves to be printed with fine outline characters are deeply engraved thereby preventing the grooves from being clogged with the ink, thus preventing the collapse of the outline characters.

In particular, when an infrared laser corresponding the absorption wavelength of the photothermal converting agent is used for engraving, the relief forming layer is selectively removed at higher sensitivity, whereby the resultant relief layer has a sharp image. The infrared laser used in the step (2) is preferably a CO₂ laser or a semiconductor laser from the viewpoints of productivity and cost. In particular, a fiber-coupled semiconductor infrared laser is preferred. In general, the oscillation of a semiconductor laser is more efficient than that of a CO₂ laser, which allows the reduction of cost and size of the laser system. In addition, the smallness of the laser facilitates arrangement of the devices. Further, the beam shape can be controlled by appropriately treating the fibers. The absorption maximum wavelength of the semiconductor laser used herein may be from 700 nm to 1300 nm, preferably from 800 nm to 1200 nm, more preferably from 860 nm to 1200 nm, and particularly preferably from 900 nm to 1100 nm.

In the method for manufacturing a relief printing plate of the invention, the step (2) may be followed by, as necessary the following steps (3) to step (5):

step (3): rinsing the surface of the engraved relief layer with water or a liquid composed mainly of water (rinsing step);

step (4): drying the engraved relief layer (drying step); and

step (5): applying energy to the engraved relief layer thereby further crosslinking the relief layer (post-crosslinking step).

When shavings are adhering to the engraved surface, the step (3) may added, in which the engraved surface is rinsed with water or a liquid composed mainly of water to remove the shavings. Examples of rinsing methods include a method of washing with tap water, a method of spraying high pressure water, and a method of brushing the engraved surface in the presence of mostly water using a batch type or conveyor washing machine known as a developing machine for photosensitive resin letterpress printing plates. If slimy shavings persist, they may be removed with a rinse agent containing a surfactant.

After the step (3) for rinsing the engraved surface is carried out, the step (4) is preferably carried out, in which the engraved relief forming layer is dried to evaporate the rinse agent.

Further, as necessary, the step (5) may be carried out, in which the relief forming layer is further crosslinked. The additional crosslinking step (5) further strengthens the relief formed by engraving.

As described above, the relief printing plate of the invention having a relief layer on a support may be obtained.

The thickness of the relief layer in the relief printing plate is preferably from 0.05 mm to 10 mm, more preferably from 0.05 mm to 7 mm, and particularly preferably from 0.05 min to 3 mm, from a viewpoint that various flexography suitabilities such as wear resistance and ink transfer properties are satisfied.

In addition, it is preferable that the Shore A hardness of the relief layer in the relief printing plate be from 50° to 90°.

When the Shore A hardness of the relief layer is 50° or more, even when a fine dot formed by engraving undergoes a strong printing pressure of a letterpress printing machine, the dot does not fall down and is not crushed, and normal printing may be performed. On the other hand, when the Shore A hardness of the relief layer is 90° or less, even in the case of flexography in which a printing pressure is kiss touch, printing shortage in a solid area may be prevented.

The Shore A hardness in the present specification is a value obtained by using a durometer (spring-type rubber hardness scale) for indentation-deforming the surface of an object to be measured with an indenter (also called a press needle), and measuring the value of the deformation amount (indentation depth).

The relief printing plate produced according to the manufacture method of the invention allows printing with an oil-based ink or a UV ink using a letterpress printing machine, and also allows printing with a UV ink using a flexographic printing machine.

Embodiments of the present invention are described below.

<1> A relief printing plate precursor for laser engraving comprising a relief forming layer formed by crosslinking a resin composition for laser engraving comprising a compound (A) having at least two isocyanate groups in its molecule, and a polymer compound (B) having at least one substituent selected from the group consisting of a hydroxyl group and —NHR,

wherein R represents a hydrogen atom, a linear alkyl group, a branched alkyl group, an alkenyl group, an alkynyl group, a cycloalkyl group, an alkoxy group, an aryl group, or a heterocyclic group.

<2> The relief printing plate precursor for laser engraving of <1>, wherein the glass transition temperature of the polymer compound (B) having at least one substituent selected from the group consisting of a hydroxyl group and —NHR is higher than 20° C., and 200° C. or lower.

<3> The relief printing plate precursor for laser engraving of <1> or <2>, wherein the polymer compound (B) having at least one substituent selected from the group consisting of a hydroxyl group and —NHR is at least one selected from the group consisting of acrylic resins and polyvinyl acetals.

<4> The relief printing plate precursor for laser engraving of any one of <1> to <3>, wherein the polymer compound (B) having at least one substituent selected from the group consisting of a hydroxyl group and —NHR is polyvinyl butyral.

<5> The relief printing plate precursor for laser engraving of any one of <1> to <4>, wherein the compound (A) having at least two isocyanate groups in its molecule has a carbon-sulfur bond in a moiety that links two isocyanate groups.

<6> The relief printing plate precursor for laser engraving of any one of <1> to <5>, wherein the resin composition for laser engraving further comprises a polymerizable compound (C).

<7> The relief printing plate precursor for laser engraving of any one of <1> to <6>, wherein the resin composition for laser engraving further comprises a polymerization initiator (D).

<8> The relief printing plate precursor for laser engraving of any one of <1> to <7>, wherein the resin composition for laser engraving further comprises a photothermal converting agent (E) which absorbs light having a wavelength of from 700 nm to 1300 nm.

<9> A resin composition for laser engraving comprising a compound (A) having at least two isocyanate groups in its molecule, and a polymer compound (B) having at least one substituent selected from the group consisting of a hydroxyl group and —NHR, wherein R represents a hydrogen atom, a linear alkyl group, a branched alkyl group, an alkenyl group, an alkynyl group, a cycloalkyl group, an alkoxy group, an aryl group, or a heterocyclic group.

<10> The resin composition for laser engraving of <9>, wherein the glass transition temperature of the polymer compound (B) having at least one substituent selected from the group consisting of a hydroxyl group and —NHR is higher than 20° C., and 200° C. or lower.

<11> The resin composition for laser engraving of <9> or <10>, wherein the polymer compound (B) having at least one substituent selected from the group consisting of a hydroxyl group and —NHR is at least one selected from the group consisting of acrylic resins and polyvinyl acetals.

<12> The resin composition for laser engraving of <11>, wherein the polymer compound (B) having at least one substituent selected from the group consisting of a hydroxyl group and —NHR is polyvinyl butyral.

<13> The resin composition for laser engraving of any one of <9> to <12>, wherein the compound (A) having at least two isocyanate groups in its molecule has a carbon-sulfur bond in a moiety that links two isocyanate groups.

<14> A method for manufacturing a relief printing plate comprising:

laser-engraving the relief forming layer of the relief printing plate precursor for laser engraving of any one of <1> to <8> to form a relief layer.

<15> The method for manufacturing a relief printing plate of <14>, wherein the method further comprises crosslinking the relief forming layer by heat.

<16> A relief printing plate comprising a relief layer made by the method for manufacturing a relief printing plate of <14> or <15>.

<17> The relief printing plate of <16>, wherein the thickness of the relief layer is from 0.05 mm to 10 mm.

<18> The relief printing plate of <16> or <17>, wherein the Shore A hardness of the relief layer is from 50° to 90°.

All publications, patent applications, and technical standards mentioned in this specification are herein incorporated by reference to the same extent as if each individual publication, patent application, or technical standard was specifically and individually indicated to be incorporated by reference.

### EXAMPLES

The present invention is described below in further detail with reference to examples, but the invention is not limited to these examples. Unless otherwise specified, the weight average molecular weights (Mws) of the polymers used in the examples are the measurements by GPC.

### Synthesis of polyfunctional isocyanate compound I-4

50 g of trimethylol propane (manufactured by Tokyo Chemical Industry Co., Ltd.), 188 g of 1,6-hexane diisocyanate (manufactured by Tokyo Chemical Industry Co., Ltd.), and 300 g of 2-butanone (manufactured by Wako Pure Chemical Industries, Ltd.) were placed in a three-necked flask equipped with a stirring blade and a cooling tube, and stirred under heat reflux. After 5 hours, 2-butanone was removed under reduced pressure, thereby obtaining 238 g of a polyfunctional isocyanate compound I-4 (the exemplary compound I-4). The structure of the polyfunctional isocyanate compound I-4 was determined by ¹H-NMR.

### Synthesis of polyfunctional isocyanate compounds I-5 to I-15

Polyfunctional isocyanate compounds I-5 to I-15 were produced in the same manner as in Synthesis of polyfunctional isocyanate compound I-4, except that trimethylol propane was changed to respectively corresponding alcohol compounds, thiol compounds, or amine compounds (the amounts of which are equivalent to the amount of trimethyl propane used in the synthesis of polyfunctional isocyanate compound I-4), and 1,6-hexane diisocyanate was changed to respectively corresponding diisocyanate compounds (the amounts of which are equivalent to the amount of 1,6-hexane diisocyanate used in the synthesis of polyfunctional isocyanate compound I-4). The structures of the polyfunctional isocyanate compounds I-5 to I-15 (the exemplary compounds I-5 to I-15) were determined by ¹H-1-NMR.

### Example 1

### 1. Preparation of Crosslinkable Resin Composition for Laser Engraving

50 g of DENKA BUTYRAL #3000-2 (trade name; polyvinyl butyral manufactured by Denki Kagaku Kogyo Kabushiki Kaisha; Mw: 90000) as the specific polymer compound (B) and 47 g of propylene glycol monomethyl ether acetate as the solvent were placed in a three-necked flask equipped with a stirring blade and a cooling tube, and heated at 70° C. for 120 minutes under stirring to dissolve the polymer. Subsequently, the solution was cooled to 40° C., to which 15 g of a monomer (M-1) (represented by the following structure) as the polymerizable compound (C) (polyfunctional compound), 8 g of methacrylic acid dodecyl (BLEMMER LMA, manufactured by NOF Corporation) as the polymerizable compound (monofunctional compound), 1.6 g of tert-butyl benzoyl peroxide (PERBUTYL Z, manufactured by NOF Corporation) as the polymerization initiator (D), and 1 g of KETJEN BLACK EC600JD (carbon black manufactured by Lion Corporation) as the photothermal converting agent (E) were added, and the mixture was stirred for 30 minutes. Subsequently, 15 g of hexamethylene diisocyanate (manufactured by Wako Pure Chemical Industries, Ltd.) (the exemplary compound I-1) as the polyfunctional isocyanate (A) was added, and the mixture was stirred at 40° C. for 10 minutes. As a result of the above procedure, a fluid coating solution 1 for forming a crosslinkable relief forming layer (crosslinkable resin composition for laser engraving) was obtained.

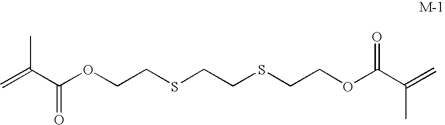

### 2. Manufacture of Relief Printing Plate Precursor for Laser Engraving

A spacer (frame) having a specified thickness was mounted on a PET substrate, and the coating solution 1 for forming a crosslinkable relief forming layer obtained by the above-described procedure was quietly cast over the substrate without overflow from the spacer (frame). The substrate was dried in an oven at 70° C. for 3 hours to form a relief forming layer having a thickness of about 1 mm, thus obtaining a relief printing plate precursor 1 for laser engraving.

### 3. Manufacture of Relief Printing Plate

The relief forming layer of the precursor thus obtained was heated at 80° C. for 3 hours, and then at 100° C. for 3 hours, thereby thermally crosslinking the relief forming layer.

The crosslinked relief forming layer was subjected to laser engraving by any of the two procedures described below.

As the CO₂ laser engraving machine, a high-quality CO₂ laser marker ML-9100 (trade name, manufactured by KEYENCE Corporation) was used for engraving by laser irradiation. The printing plate precursor 1 for laser engraving was subjected to raster engraving using the CO₂ laser engraving machine at a laser power of 12 W, a head speed of 200 mm/second, and a dot pitch of 2400 DPI, thereby forming a solid area of one square centimeter.

As the semiconductor laser engraving machine, a laser recording machine equipped with a fiber-coupled semiconductor laser (FC-LD) SDL-6390 (trade name, manufactured by JDSU, wavelength: 915 nm) having a maximum power of 8.0 W was used. Using the semiconductor laser engraving machine, a solid area of one square centimeter was formed by raster engraving at a laser power of 7.5 W, a head speed of 409 mm/second, and a dot pitch of 2400 DPI.

The thickness of the relief layer of the relief printing plate was about 1 mm.

The Shore A hardness of the relief layer was 75° as measured by the above-described measurement method. In the below-described examples and comparative examples, the Shore hardness A was measured in the same manner as in Example 1.

### Examples 2 to 28 and Comparative Examples 1 to 3

### 1. Preparation of Crosslinkable Resin Composition for Laser Engraving

Coating solutions for forming crosslinkable relief forming layers (crosslinkable resin compositions for laser engraving) were prepared in the same manner as in Example 1, except that the polyfunctional isocyanate (A) and the specific polymer compound (B) were replaced with the polyfunctional isocyanate (A), the specific polymer compound (B), or a comparison binder polymer listed in Table 1.

TABLE 1

| | Specific polymer | | | | | | |
|---|---|---|---|---|---|---|---|
| | compound (B) and | Polyfunctional isocyanate (A) | | | | | |
| | comparative binder | | Number of | Presence of | Polymerizable | Polymerization | |
| | polymer | Compound | NCO group | S atom | compound (C) | initiator (D) | Photothermal converting agent (E) |
| Example 1 | #3000-2 | I-1 | 2 | Absent | M-1 | PERBURYL Z | KETJEN BLACK EC600JD |
| Example 2 | #3000-2 | I-2 | 2 | Absent | M-1 | PERBURYL Z | KETJEN BLACK EC600JD |
| Example 3 | #3000-2 | I-3 | 2 | Absent | M-1 | PERBURYL Z | KETJEN BLACK EC600JD |
| Example 4 | #3000-2 | I-4 | 3 | Absent | M-1 | PERBURYL Z | KETJEN BLACK EC600JD |
| Example 5 | #3000-2 | I-5 | 4 | Absent | M-1 | PERBURYL Z | KETJEN BLACK EC600JD |
| Example 6 | #3000-2 | I-6 | 6 | Absent | M-1 | PERBURYL Z | KETJEN BLACK EC600JD |
| Example 7 | #3000-2 | I-7 | 2 | Present | M-1 | PERBURYL Z | KETJEN BLACK EC600JD |
| Example 8 | #3000-2 | I-8 | 2 | Present | M-1 | PERBURYL Z | KETJEN BLACK EC600JD |
| Example 9 | #3000-2 | I-9 | 2 | Present | M-1 | PERBURYL Z | KETJEN BLACK EC600JD |
| Example 10 | #3000-2 | I-10 | 2 | Present | M-1 | PERBURYL Z | KETJEN BLACK EC600JD |
| Example 11 | #3000-2 | I-11 | 2 | Present | M-1 | PERBURYL Z | KETJEN BLACK EC600JD |
| Example 12 | #3000-2 | I-12 | 2 | Present | M-1 | PERBURYL Z | KETJEN BLACK EC600JD |
| Example 13 | #3000-2 | I-13 | 3 | Present | M-1 | PERBURYL Z | KETJEN BLACK EC600JD |
| Example 14 | #3000-2 | I-14 | 4 | Present | M-1 | PERBURYL Z | KETJEN BLACK EC600JD |
| Example 15 | #3000-2 | I-15 | 6 | Present | M-1 | PERBURYL Z | KETJEN BLACK EC600JD |
| Example 16 | POLYMENT | I-1 | 2 | Absent | M-1 | PERBURYL Z | KETJEN BLACK EC600JD |
| | NK-350 | | | | | | |
| Example 17 | OH-containing acrylic | I-1 | 2 | Absent | M-1 | PERBURYL Z | KETJEN BLACK EC600JD |
| | resin | | | | | | |
| Example 18 | POLYMENT NK-350 | I-7 | 2 | Present | M-1 | PERBURYL Z | KETJEN BLACK EC600JD |
| Example 19 | OH-containing acrylic | I-7 | 2 | Present | M-1 | PERBURYL Z | KETJEN BLACK EC600JD |
| | resin | | | | | | |
| Example 20 | Novolac resin | I-1 | 2 | Absent | M-1 | PERBURYL Z | KETJEN BLACK EC600JD |
| Example 21 | Novolac resin | I-7 | 2 | Present | M-1 | PERBURYL Z | KETJEN BLACK EC600JD |
| Example 22 | Poly bd | I-5 | 4 | Absent | M-1 | PERBURYL Z | KETJEN BLACK EC600JD |
| Example 23 | Poly bd | I-14 | 4 | Present | M-1 | PERBURYL Z | KETJEN BLACK EC600JD |
| Example 24 | #3000-2 | I-1 | 2 | Absent | Absent | Absent | Absent |
| Example 25 | #3000-2 | I-1 | 2 | Absent | M-1 | Absent | Absent |
| Example 26 | #3000-2 | I-1 | 2 | Absent | Absent | Absent | KETJEN BLACK EC600JD |
| Example 27 | #3000-2 | I-1 | 2 | Absent | M-1 | PERBURYL Z | Absent |
| Example 28 | #3000-2 | I-16 | 2 | Absent | M-1 | PERBURYL Z | KETJEN BLACK EC600JD |
| Comparative | #3000-2 | Absent | — | — | Absent | Absent | Absent |
| Example 1 | | | | | | | |
| Comparative | TR2000 | Sulfur | — | Present | Absent | Absent | Absent |
| Example 2 | | | | | | | |
| Comparative | Polyurethane | Absent | — | — | Absent | Absent | Absent |
| Example 3 | | | | | | | |

The polyfunctional isocyanates (A) (1-1 to I-15) listed in Table 1 used in the examples and comparative examples are the above-described exemplary compounds, and details of the specific polymer compounds (B) and comparative binder polymers are described below.

#3000-2: vinyl butyral/vinyl alcohol/vinyl acetate copolymer (80/19/1 (wt %), Mw: 90,000, Tg: 68° C., manufactured by Denki Kagaku Kogyo Kabushiki Kaisha)

OH-containing acrylic resin: cyclohexyl methacrylate/2-hydroxyethyl methacrylate copolymer (70/30 (mol %), Mw: 50,000, Tg: 80° C.)

Novolac resin: novolac resin (Mw: 20,000, Tg: 80° C.) obtained from octyl phenol/formaldehyde (50/50)

Polyurethane: polyurethane (Mw: 90,000) obtained from tolylene diisocyanate/polypropylene glycol (Mw: 2,000, Tg≦0° C.) (50/50)

TR2000 (manufactured by JSR): styrene-butadiene copolymer (Tg: 100° C.)

POLYMENT NK-350: primary amino group-containing alkyl polymer having polyethylene imine grafted at a side chain thereof (Mw: 100,000, Tg: 40° C., manufactured by Nippon Shokubai Co., Ltd.)

Poly bd: hydroxyl group-terminated polybutadiene (Mn: 2,800, Tg≦0° C., manufactured by Idemitsu Kosan Co., Ltd.)

Method of determining Tg of specified polymer compound (B) 10 mg of a sample was placed in a measurement pan of a differential scanning calorimeter (DSC) (trade name: Q2000, manufactured by TA Instruments), and heated from 30° C. to 250° C. at a rate of 10° C./min under a nitrogen air (1st-run), followed by cooling to 0° C. at a rate of −10° C./min. After that, the sample was again heated from 0° C. to 250° C. (2nd-run). The temperature at which the base line was shifted in the 2nd-run was regarded as Tg.

### 2. Manufacture of Relief Printing Plate Precursors for Laser Engraving

Relief printing plate precursors for laser engraving of Examples 2 to 28 and Comparative Examples 1 to 3 were obtained in the same manner as in Example 1, except that the coating solution 1 for forming a crosslinkable relief forming layer was replaced with the coating solutions of Examples 2 to 28 and Comparative Examples 1 to 3 for forming crosslinkable relief forming layers, respectively.

### 3. Manufactured of Relief Printing Plate

Relief printing plates of Examples 2 to 28 and Comparative Examples 1 to 3 were obtained in the same manner as in Example 1, through the thermal crosslinking of the relief forming layers of the relief printing plate precursors of Examples 2 to 28 and Comparative Examples 1 to 3, followed by engraving to form relief layers.

The thicknesses of the relief layers of these relief printing plates were about 1 mm.

### 4. Evaluation of Relief Printing Plates

The relief printing plates were examined for the following properties. The results are shown in Table 2.

(4-1) Engraved Depth

The “engraved depth” of the relief layers formed by laser engraving the relief forming layers of the relief printing plate precursors of Examples 1 to 28 and the relief printing plates of Comparative Examples 1 to 3 were measured as described below. The “engraved depth” refers to the difference of the position (height) of engraved and not engraved regions in the cross section of the relief layer. In the examples, the “engraved depth” was measured by observing the cross section of the relief layer using an ultra-deep color 3D profile measuring microscope (trade name: VK9510, manufactured by Keyence Corporation). The greater the engraved depth, the higher the engraving sensitivity. The results are shown in Table 2, organized by the type of the laser used for engraving.

(4-2) Plastic Deformation Rate

The plastic deformation rate was measured using a microhardness tester GS-706 (trade name, manufactured by Teclock) before and after indentation for 10 seconds under a load of 300 mN followed by relaxation.

(4-3) Printing Durability

The relief printing plate was mounted on a printing machine (trade name: ITM-4, manufactured by Iyo Kikai Seisakusho Co., Ltd.), and used for continuous printing on a print paper (trade name: FULL COLOR FORM M 70, manufactured by Nippon Paper Group, Inc., thickness of 100 μm) with an undiluted water-based ink (trade name: AQUA SPZ16 PINK, manufactured by Toyo Ink Mfg. Co., Ltd.). The 1 to 10% highlight areas on the printed material were observed, and the printing was terminated when unprinted dots were found. The length (meter) of the paper printed until the termination of printing was used as the index. The greater the value, the better the printing durability.

TABLE 2

| | Plastic | Printing | Engraved depth | Engraved depth |
|---|---|---|---|---|
| | deformation | durability | (μm) | (μm) |
| | rate (%) | (m) | (FC-LD) | (CO₂ laser) |
| Example 1 | 6 | 2000 | 400 | 322 |
| Example 2 | 5 | 2000 | 390 | 312 |
| Example 3 | 5 | 2100 | 390 | 312 |
| Example 4 | 4 | 2000 | 395 | 316 |
| Example 5 | 3 | 2100 | 385 | 308 |
| Example 6 | 3 | 2000 | 385 | 308 |
| Example 7 | 6 | 2000 | 430 | 344 |
| Example 8 | 4 | 2100 | 425 | 340 |
| Example 9 | 4 | 2100 | 420 | 336 |
| Example 10 | 5 | 2000 | 430 | 344 |
| Example 11 | 5 | 2000 | 430 | 344 |
| Example 12 | 4 | 2000 | 425 | 340 |
| Example 13 | 5 | 2000 | 425 | 340 |
| Example 14 | 4 | 2000 | 420 | 336 |
| Example 15 | 4 | 2100 | 420 | 336 |
| Example 16 | 8 | 1700 | 390 | 312 |
| Example 17 | 8 | 1700 | 395 | 316 |
| Example 18 | 8 | 1800 | 415 | 330 |
| Example 19 | 9 | 1700 | 420 | 336 |
| Example 20 | 6 | 1900 | 385 | 308 |
| Example 21 | 7 | 1800 | 410 | 324 |
| Example 22 | 10 | 1600 | 390 | 312 |
| Example 23 | 9 | 1600 | 415 | 330 |
| Example 24 | 8 | 1600 | 345 | 276 |
| Example 25 | 7 | 1800 | 345 | 276 |
| Example 26 | 8 | 1600 | 400 | 322 |
| Example 27 | 6 | 2000 | 345 | 276 |
| Example 28 | 6 | 2000 | 420 | 336 |
| Comparative | 35 | 500 | 345 | 276 |
| Example 1 | | | | |
| Comparative | 5 | 2000 | 290 | 232 |
| Example 2 | | | | |
| Comparative | 30 | 600 | 380 | 304 |
| Example 3 | | | | |

As shown in Table 2, the relief printing plates of examples made using the resin composition for laser engraving containing the polyfunctional isocyanate (A) and the specific polymer compound (B) were superior to the relief printing plates of comparative examples in the elasticity, ink transfer properties, and printing durability of the relief layer. Therefore, the relief printing plates of examples exert good printability over a long period of time. In addition, the great engraved depths of the relief printing plates of the invention indicate that they exert good engraving sensitivity and high productivity during platemaking.

The comparison between Examples 1 to 6 and Examples 7 to 15 indicate that those containing an S atom in the molecule of the polyfunctional isocyanate (A) achieve greater engraved depths and higher sensitivity.

When the same relief printing plate precursors were used, a greater engraved depth was achieved through the use of the platemaking apparatus equipped with a fiber-coupled semiconductor laser and an FC-LD as the light source.

What is claimed is:

1. A relief printing plate precursor for laser engraving comprising a relief forming layer formed by crosslinking a resin composition for laser engraving comprising a compound (A) having at least two isocyanate groups in a molecule and a polymer compound (B) having at least one substituent selected from the group consisting of a hydroxyl group and —NHR,
wherein R represents a hydrogen atom, a linear alkyl group, a branched alkyl group, an alkenyl group, an alkynyl group, a cycloalkyl group, an alkoxy group, an aryl group, or a heterocyclic group.

2. The relief printing plate precursor for laser engraving of claim 1, wherein the glass transition temperature of the polymer compound (B) is higher than 20° C. but no more than 200° C.

3. The relief printing plate precursor for laser engraving of claim 1, wherein the polymer compound (B) is at least one selected from the group consisting of acrylic resins and polyvinyl acetals.

4. The relief printing plate precursor for laser engraving of claim 1, wherein the polymer compound (B) is polyvinyl butyral.

5. The relief printing plate precursor for laser engraving of claim 1, wherein the compound (A) has a carbon-sulfur bond in a moiety that links two isocyanate groups.

6. The relief printing plate precursor for laser engraving of claim 1, wherein the resin composition for laser engraving further comprises a polymerizable compound (C).

7. The relief printing plate precursor for laser engraving of claim 1, wherein the resin composition for laser engraving further comprises a polymerization initiator (D).

8. The relief printing plate precursor for laser engraving of claim 1, wherein the resin composition for laser engraving further comprises a photothermal conversion agent (E) which absorbs light having a wavelength of from 700 nm to 1300 nm.

9. A resin composition for laser engraving comprising a compound (A) having at least two isocyanate groups in a molecule, and a polymer compound (B) having at least one substituent selected from the group consisting of a hydroxyl group and —NHR, wherein R represents a hydrogen atom, a linear alkyl group, a branched alkyl group, an alkenyl group, an alkynyl group, a cycloalkyl group, an alkoxy group, an aryl group, or a heterocyclic group.

10. The resin composition for laser engraving of claim 9, wherein the glass transition temperature of the polymer compound (B) is higher than 20° C. but no more than 200° C.

11. The resin composition for laser engraving of claim 9, wherein the polymer compound (B) is at least one selected from the group consisting of acrylic resins and polyvinyl acetals.

12. The resin composition for laser engraving of claim 11, wherein the polymer compound (B) is polyvinyl butyral.

13. The resin composition for laser engraving of claim 9, wherein the compound (A) has a carbon-sulfur bond in a moiety that links two isocyanate groups.

14. A method for manufacturing a relief printing plate, the method comprising:
laser-engraving the relief forming layer of the relief printing plate precursor for laser engraving of claim 1 to form a relief layer.

15. The method for manufacturing a relief printing plate of claim 14, further comprising crosslinking the relief forming layer by heat.

16. A relief printing plate comprising a relief layer and made by the method for manufacturing a relief printing plate of claim 14.

17. The relief printing plate of claim 16, wherein the thickness of the relief layer is from 0.05 mm to 10 mm.

18. The relief printing plate of claim 16, wherein the Shore A hardness of the relief layer is from 50° to 90°.
